(19) United States
(12) Patent Application Publication
(10) Pub. No.: US 2025/0294967 A1
(43) Pub. Date: Sep. 18, 2025

(54) DISPLAY PANEL, PREPARING METHOD THEREOF, AND DISPLAY DEVICE

(71) Applicants: Hefei Visionox Technology Co., Ltd., Hefei (CN); Visionox Technology Inc., Kunshan (CN)

(72) Inventors: Tingxia HE, Hefei (CN); Liping XU, Hefei (CN); Zhengkui DONG, Hefei (CN); Yingzi ZHAO, Hefei (CN)

(73) Assignees: Hefei Visionox Technology Co., Ltd., Hefei (CN); Visionox Technology Inc., Kunshan (CN)

(21) Appl. No.: 18/977,981

(22) Filed: Dec. 12, 2024

Related U.S. Application Data
(63) Continuation of application No. PCT/CN2024/108935, filed on Jul. 31, 2024.

(30) Foreign Application Priority Data
Mar. 12, 2024 (CN) 202410284339.2
Mar. 27, 2024 (CN) 202410364382.X
Mar. 29, 2024 (CN) 202410382905.3

(51) Int. Cl. H10K 59/122; H10K 59/12; H10K 59/80

(52) U.S. Cl. CPC H10K 59/122; H10K 59/1201; H10K 59/873

(57) ABSTRACT

The present disclosure provides a display panel, a preparing method thereof and a display device. The display panel includes a substrate together with a pixel defining layer and a first packaging layer located on the substrate, the first packaging layer is located on a side, away from the substrate, of the pixel defining layer, and compactness of at least a portion of the pixel defining layer is greater than compactness of the first packaging layer, or a refractive index of at least a portion of the pixel defining layer is greater than a refractive index of the first packaging layer. In the display panel, by increasing compactness of the pixel defining layer, a degree to which the pixel defining layer is etched can be reduced in a process of etching the first packaging layer, so as to protect a structure under the pixel defining layer.

### CROSS-REFERENCE TO RELATED APPLICATIONS

This application is a continuation of International Application No. PCT/CN2024/108935 filed on Jul. 31, 2024, which claims priority to a Chinese Patent Application No. 202410284339.2 filed on Mar. 12, 2024, a Chinese Patent Application No. 202410364382.X filed on Mar. 27, 2024, and a Chinese Patent Application No. 202410382905.3 filed on Mar. 29, 2024. Both applications are incorporated herein by reference in their entireties.

### TECHNICAL FIELD

The present disclosure relates to a field of display technology, and in particular, to a display panel, a preparing method thereof, and a display device.

### BACKGROUND

Organic Light-Emitting Diode (OLED) is an organic thin film electroluminescent unit that has been greatly concerned and widely used in electronic display products due to its advantages such as simple preparation process, low cost, small power consumption, high brightness, wide viewing angle, high contrast and available flexible display.

However, yield of display panels is difficult to be further improved in the current electronic display products that are limited by their own structural designs.

### SUMMARY

A first aspect of the present disclosure provides a display panel which includes a substrate together with a pixel defining layer and a first packaging layer located on the substrate, the first packaging layer being located on a side, away from the substrate, of the pixel defining layer, compactness of at least a portion of the pixel defining layer being greater than compactness of the first packaging layer, or a refractive index of at least a portion of the pixel defining layer being greater than a refractive index of the first packaging layer.

During preparation of the display panel, the first packaging layer will be etched. In the above solution, by increasing compactness or a refractive index of the pixel defining layer, a degree to which the pixel defining layer is etched can be reduced in a process of etching the first packaging layer, so as to protect a structure under the pixel defining layer, thereby ensuring yield of the display panel.

In a specific embodiment of the first aspect of the present disclosure, compactness of another one sub-defining layer, away from the first packaging layer, of the at least two sub-defining layers is greater than or equal to compactness of the first packaging layer, or a refractive index of another one sub-defining layer, away from the first packaging layer, of the at least two sub-defining layers is greater than or equal to a refractive index of the first packaging layer.

In a specific embodiment of the first aspect of the present disclosure, the pixel defining layer includes at least three sub-defining layers sequentially stacked on the substrate, and along a direction away from the substrate, compactness of the sub-defining layer gradually increases, or the refractive index of the sub-defining layer gradually increases.

In a specific embodiment of the first aspect of the present disclosure, the pixel defining layer includes a first sub-defining layer, a second sub-defining layer and a third sub-defining layer which are sequentially stacked on the substrate, and compactness of the second sub-defining layer is greater than compactness of the first sub-defining layer and compactness of the third sub-defining layer, or a refractive index of the second sub-defining layer is greater than a refractive index of the first sub-defining layer and a refractive index of the third sub-defining layer.

In a specific embodiment of the first aspect of the present disclosure, compactness of the third sub-defining layer is less than or equal to compactness of the first packaging layer, or the refractive index of the third sub-defining layer is less than or equal to the refractive index of the first packaging layer; or compactness of the first sub-defining layer is less than or equal to compactness of the first packaging layer, or the refractive index of the first sub-defining layer is less than or equal to the refractive index of the first packaging layer; or compactness of the first sub-defining layer is equal to compactness of the third sub-defining layer, or the refractive index of the first sub-defining layer is equal to the refractive index of the third sub-defining layer.

In a specific embodiment of the first aspect of the present disclosure, the pixel defining layer includes at least two sub-defining layers sequentially stacked on the substrate, compactness of one sub-defining layer, close to the substrate, of the at least two sub-defining layers is greater than compactness of other sub-defining layers, or one refractive index of the sub-defining layer, close to the substrate, of the at least two sub-defining layers is greater than a refractive index of other sub-defining layers.

In a specific embodiment of the first aspect of the present disclosure, compactness of another one sub-defining layer, close to the first packaging layer, of the at least two sub-defining layers is greater than or equal to compactness of the first packaging layer; or a refractive index of another one sub-defining layer, close to the first packaging layer, of the at least two sub-defining layers is greater than or equal to a refractive index of the first packaging layer.

In a specific embodiment of the first aspect of the present disclosure, the pixel defining layer includes at least three sub-defining layers sequentially stacked on the substrate, and along a direction away from the substrate, compactness of the sub-defining layers gradually decreases or a refractive index of the sub-defining layers gradually decreases.

A second aspect of the present disclosure provides a display panel which includes a substrate and a pixel defining layer located on the substrate, a surface of the pixel defining layer away from the substrate is a first surface, and a surface of the pixel defining layer close to the substrate is a second surface, and an orthogonal projection, located on the substrate, of the first surface is located within an orthogonal projection, located on the substrate, of the second surface, and the pixel defining layer includes a side wall that connects the first surface and the second surface, and that is inclined relative to the surface in which the substrate is located. The pixel defining layer includes at least two sub-defining layers stacked on the substrate.

In the above solution, by designing the pixel defining layer to be composed of at least two sub-defining layers, structural parameters (such as compactness, etc.) of different portions of the pixel defining layer can be controlled, such that a degree to which different portions of the pixel defining layer are etched is controlled and a specific shape of the side wall is controlled. For example, angles at which the side walls of at least two sub-defining layers are inclined relative to a plane in which the substrate is located may be the same or different, thereby ensuring film formation quality of a film layer (such as the second electrode described below) on the pixel defining layer.

A third aspect of the present disclosure provides a display panel which includes a substrate together with a pixel defining layer and a first packaging layer located on the substrate. The first packaging layer is located on a side, away from the substrate, of the pixel defining layer, and the density of at least a portion of the pixel defining layer is greater than the density of the first packaging layer; or a negative valence element content in at least a portion of the pixel defining layer is greater than a negative valence element content in the first packaging layer, and the negative valence elements include oxygen and nitrogen.

A fourth aspect of the present disclosure provides a display panel which includes a substrate together with a pixel defining layer, light-emitting units and a packaging structure located on the substrate. The pixel defining layer is provided on one side of the substrate, the pixel defining layer surrounds and forms a pixel opening, the light-emitting unit is provided in the pixel opening and on a side, away from the substrate, of the pixel defining layer, the packaging structure is provided on a side, away from the substrate, of the light-emitting functional layer, the packaging structure includes a first packaging layer close to one side of the pixel defining layer, the pixel defining layer includes a sub-defining layer, an orthogonal projection, located on the substrate, of the first packaging layer partially overlaps with an orthogonal projection, located on the substrate, of the sub-defining layer, and an etching rate of the sub-defining layer is lower than an etching rate of the first packaging layer.

In a specific embodiment of the fourth aspect of the present disclosure, the pixel defining layer includes at least two sub-defining layers, namely a first sub-defining layer and a second sub-defining layer, the first sub-defining layer is located between the second sub-defining layer and the substrate, and under the same etching condition, an etching rate of the second sub-defining layer is lower than an etching rate of the first packaging layer.

A fifth aspect of the present disclosure provides a method for preparing a display panel, which includes: providing a substrate on which a pixel defining layer is provided, the pixel defining layer having pixel openings; forming light-emitting units in the pixel opening; forming a first packaging film on a side, away from the substrate, of the light-emitting unit, and performing an etching process on the first packaging film to form a first packaging layer, during the etching process on the first packaging film, an etching rate of a material of the pixel defining layer is lower than an etching rate of a material of the first packaging film.

A fifth aspect of the present disclosure provides another method for preparing a display panel, which includes: providing a substrate and forming a pixel defining layer on the substrate; forming a first packaging layer on the substrate on which the pixel defining layer is formed, in an case where the pixel defining layer is prepared under the same condition as the first packaging layer, a deposition rate of a material of the pixel defining layer is less than a deposition rate of a material of the first packaging layer.

### BRIEF DESCRIPTION OF THE DRAWINGS

FIG. 1 is a schematic diagram of a planar structure of a display panel provided in an embodiment of the present disclosure.

FIG. 2 is an enlarged view of a region S1 of the display panel shown in FIG. 1.

FIG. 3 is a sectional view taken along a line M-N of the display panel shown in FIG. 2.

FIG. 4 is an enlarged view of a region S2 of the display panel shown in FIG. 3.

FIG. 5A is an enlarged view of a local region of another display panel provided by an embodiment of the present disclosure.

FIG. 5B is an enlarged view of a local region of another display panel provided by an embodiment of the present disclosure.

FIG. 6A is an enlarged view of a local region of another display panel provided by an embodiment of the present disclosure.

FIG. 6B is an enlarged view of a local region of another display panel provided by an embodiment of the present disclosure.

FIG. 6C is an enlarged view of a local region of another display panel provided by an embodiment of the present disclosure.

FIG. 7A is an enlarged view of a local region of another display panel provided by an embodiment of the present disclosure.

FIG. 7B is an enlarged view of a local region of another display panel provided by an embodiment of the present disclosure.

FIG. 8A is an enlarged view of a local region of another display panel provided by an embodiment of the present disclosure.

FIG. 8B is an enlarged view of a local region of another display panel provided by an embodiment of the present disclosure.

FIG. 8C is an enlarged view of a local region of another display panel provided by an embodiment of the present disclosure.

FIG. 9 is an enlarged view of a local region of another display panel provided by an embodiment of the present disclosure.

FIG. 10A is an enlarged view of a local region of another display panel provided by an embodiment of the present disclosure.

FIG. 10B is an enlarged view of a local region of another display panel provided by an embodiment of the present disclosure.

FIG. 11 is a sectional view of a local region of a display panel provided by an embodiment of the present disclosure.

FIG. 12A is a flow chart of a method for preparing a display panel provided in an embodiment of the present disclosure.

FIG. 12B is a flow chart of another method for preparing a display panel provided in an embodiment of the present disclosure.

FIG. 12C is a flow chart of another method for preparing a display panel provided in an embodiment of the present disclosure.

FIGS. 13A to 13I are process diagrams of a method for preparing a display panel as shown in FIG. 3 provided in accordance with an embodiment of the present disclosure.

FIG. 14 is a schematic diagram of the positional relationship between a partial film layer of a display panel and an evaporation source during evaporation according to an embodiment of the present disclosure.

### DETAILED DESCRIPTIONS OF THE EMBODIMENTS

The technical solutions in the embodiments of this specification will be clearly and completely described below in connection with the drawings in the embodiments of this specification. Obviously, the embodiments described hereinafter are only a part of the embodiments of this specification instead of all embodiments. Based on the embodiments in this specification, all other embodiments obtained by an ordinary person skilled in the art without offering creative work fall within the protection scope of this specification.

In the display panel, a position of a light-emitting element (such as the light-emitting units described below) is defined by providing a pixel defining layer, and the pixel defining layer covers an anode of each of the light-emitting units (such as the first electrode described below). In a preparing process of the display panel, after the anode and the pixel defining layer are prepared, if the preparing process of a subsequent structure includes an etching process such as an etching process of the first packaging layer described below, then the etching process may etch the pixel defining layer. If the pixel defining layer is etched and damaged too much, quality of a film layer in the light-emitting units (such as a cathode of each of the light-emitting units) may be damaged. Even in a case where the pixel defining layer is etched through, the anode may be damaged.

The present disclosure provides a display panel and a method for preparing the display panel, and a display device, in order to at least solve the above technical problems. The display panel includes a substrate together with a pixel defining layer and a first packaging layer located on the substrate, the first packaging layer is located on a side, away from the substrate, of the pixel defining layer, compactness of at least a portion of the pixel defining layer is greater than compactness of the first packaging layer, or a refractive index of at least a portion of the pixel defining layer is greater than a refractive index of the first packaging layer. In the process of preparing the display panel, the first packaging layer will be etched. If uniformity of the first packaging layer is not enough during the forming process, an etching time of each region of the first packaging layer will be different. Therefore, over-etching may occur in a region where a film layer of the first packaging layer is thin or film forming quality is poor, which may cause the pixel defining layer to be damaged by etching. In the above solution of the present disclosure, by increasing compactness or a refractive index of the pixel defining layer, a degree to which the pixel defining layer is etched can be reduced in a process of etching the first packaging layer, so as to protect a structure under the pixel defining layer (such as the first electrode in the following embodiment), thereby ensuring yield of the display panel.

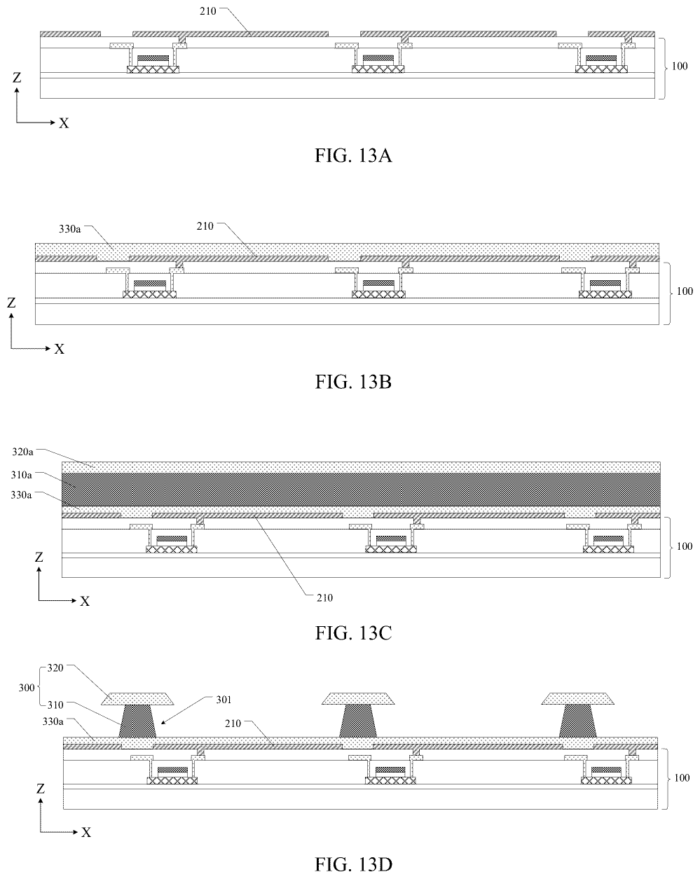

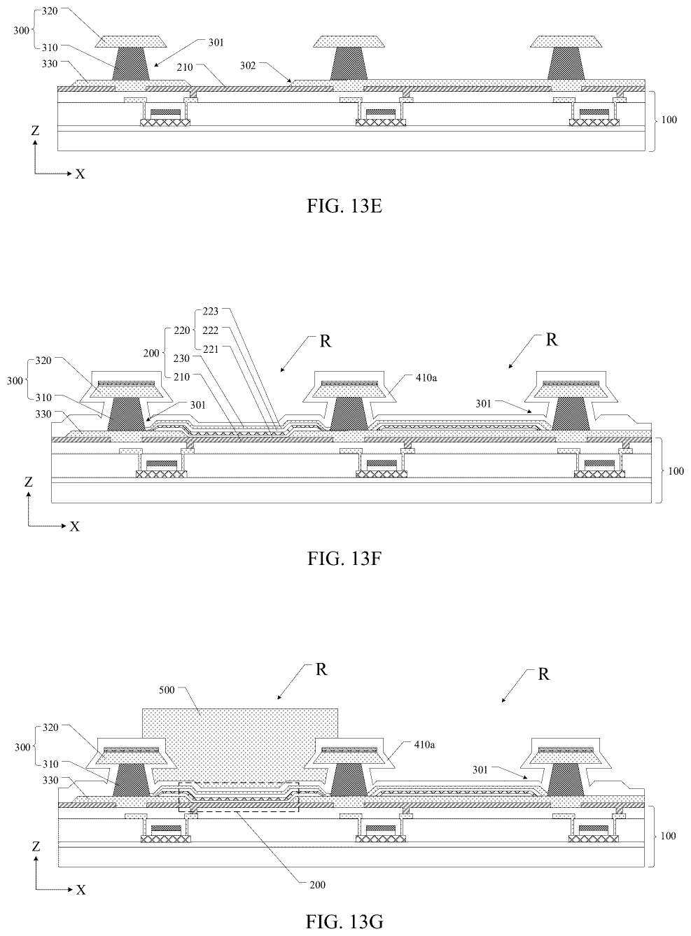

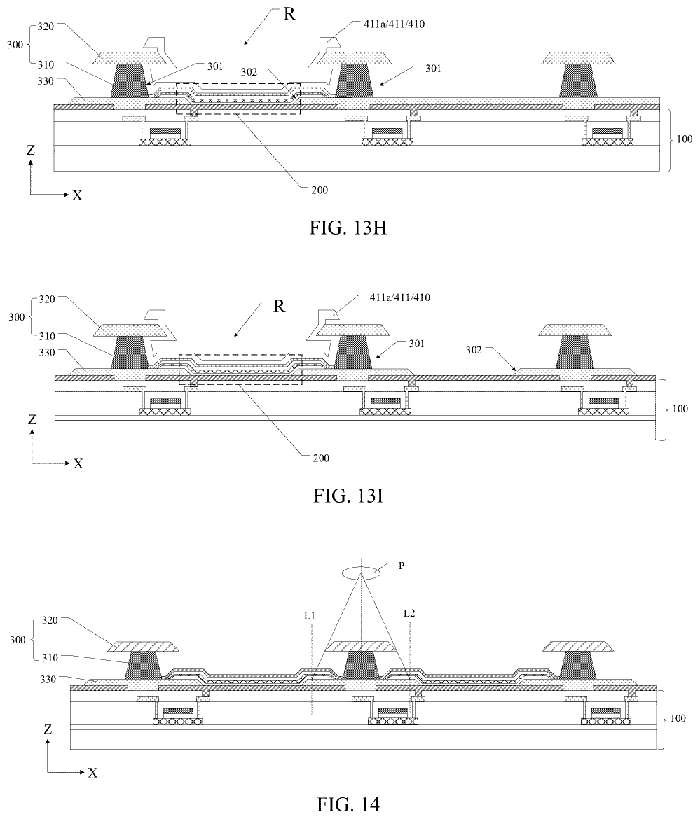

It is to be noted that a forming manner of the first packaging layer and the principle of the risk of over-etching of the pixel defining layer can be found with reference to the specific description of the embodiments related to FIGS. 13A to 13I below, and will not be redundantly described here.

The structure of the display panel in at least one embodiment of the present disclosure is described in detail below with reference to the accompanying drawings. In addition, in these drawings, a spatial rectangular coordinate system is established with the substrate as a reference to more intuitively present a positional relationship of the relevant structures in the display panel, and in the spatial rectangular coordinate system, the X-axis and the Y-axis are parallel to a plane in which the substrate is located, and the Z-axis is perpendicular to the plane in which the substrate is located.

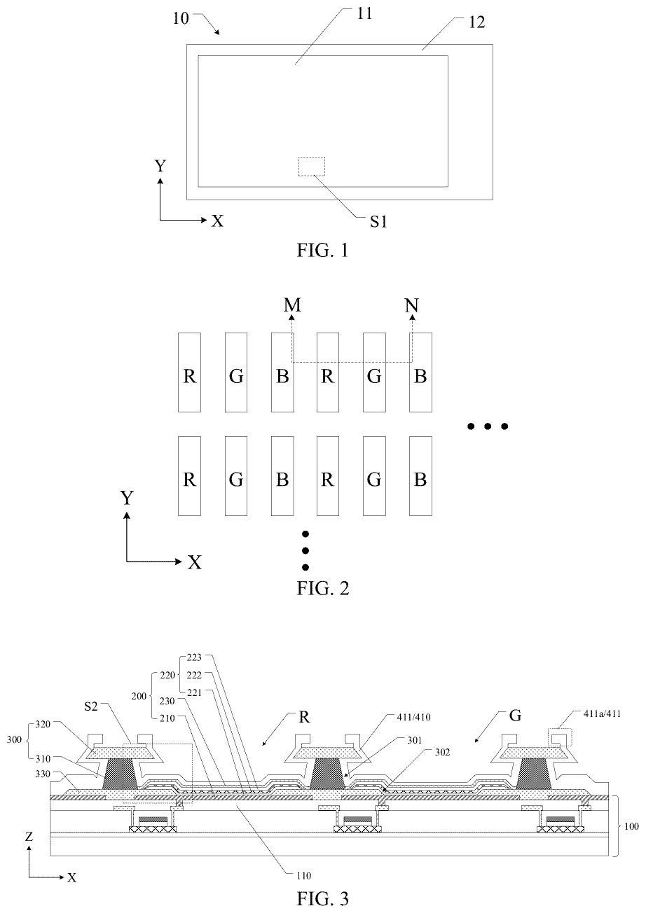

As shown in FIGS. 1 to 4, a planar region of the display panel 10 can be divided into a display region 11 and a border region 12 surrounding the display region 11. Sub-pixels (which may be referred to as minor or micro-pixels, etc.) such as R, G and B sub-pixels may be arranged in the display region 11. A physical structure of the sub-pixel may be a light-emitting unit in the following embodiments. Adjacent sub-pixels with different colors of emitted light constitute a pixel (which may be referred to as a pixel unit, a major or macro-pixel, etc.). An arrangement density of the pixels in the display region 11 represents a pixel density PPI. It is to be noted that in some embodiments of the present disclosure, a portion of wirings in the border region 12 may be arranged in the display region 11, so that the border region 12 may be designed as a single-sided border.

The physical structure of the display panel 10 may include a substrate 100 together with a pixel defining layer 330 and a first packaging layer 410 located on the substrate 100, the first packaging layer 410 is located on a side of the pixel defining layer 330 away from the substrate 100, and compactness of at least a portion of the pixel defining layer 330 is greater than compactness of the first packaging layer 410, or a refractive index of at least a portion of the pixel defining layer 330 is greater than a refractive index of the first packaging layer 410, so that an etching material used to etch the first packaging layer 410 is difficult to etch the pixel defining layer 330 relative to the first packaging layer 410, so as to reduce risk of the pixel defining layer 330 being damaged by excessive etching.

In the embodiments of the present disclosure, compactness of a film layer can be a compact degree of internal molecules or atoms of the corresponding prepared material. Compactness is an important performance index for measuring materials, which directly affects mechanical properties, thermal properties, electrical properties, etc. of the materials. Generally speaking, greater compactness means internal voids and defects in the film layer made of the material is fewer and the bonding between atoms or molecules is tighter, therefore tensile, compressive, bending and corrosion resistance of the film layer will be enhanced. For structures of the same material, a structure with a high compactness has fewer internal voids or less low-density materials than a structure with a low compactness.

It is to be noted that a compact degree of the molecules or atoms inside the film layer will also be reflected in a refractive index of the film layer, that is, the greater the compact degree of the molecules or atoms, the greater the refractive index of the film layer. In the embodiments of the present disclosure, a refractive index of the film layer can be measured by a device such as an ellipsometer. For example, a measurement principle of the ellipsometer is roughly as follows: a method known as ellipsometry uses elliptically polarized light to be incident on a sample surface, changes in a polarized state (amplitude and phase) of the reflected light are observed, and a thickness and a refractive index of a film on the sample surface are then obtained.

The measurement steps of the ellipsometer are roughly the following steps S1 to S6:
S1, calibrating an ellipsometer: before a measurement is performed, the ellipsometer is required to be calibrated to ensure that a refractive index of a sample can be accurately measured. The calibration method generally includes two steps: zero bias adjustment and scale adjustment.
S2, preparing a sample: placing a sample to be measured on a sample table of the ellipsometer.
S3, measuring a phase difference: adjusting the parameters of the instrument so that the ellipsometer outputs a minimum signal. The ellipsometer will measure a phase difference of the sample, which is proportional to a refractive index of the sample.
S4, calculating a refractive index: according to a working principle of the ellipsometer, a refractive index of the sample is calculated by measuring the phase difference.
S5, taking an average value of multiple measurements: in order to improve accuracy of measurement results, it is generally necessary to take multiple measurements and take the average value. When multiple measurements are taken, it is necessary to pay attention to maintain stability of the sample and avoid interference from external factors.
S6, controlling environmental conditions: since temperature and humidity have a certain impact on the refractive index of the sample, it is necessary to control the environmental conditions during measurement to keep the sample stable.

The measurement of a film thickness is also based on a principle of elliptically polarized light. When elliptically polarized light is incident on the sample surface, after multiple reflections and refractions of the film, a polarized state of the reflected light will be changed. By analyzing this change, the thickness of the film can be determined.

For example, a measurement range of an ellipsometer generally includes a certain range of a transparent film thickness and a refractive index, such as a transparent film thickness range of 0-300 nm and a refractive index range of 1.30-2.49.

For example, a measurement accuracy of the ellipsometer is crucial to the measurement result, and the measurement accuracy of the ellipsometer can generally be up to +2 nm.

For example, an ellipsometer may use a laser such as a helium-neon laser or a semiconductor laser as a light source, which typically has a wavelength of 632.8 nm or 635 nm.

It is to be noted that in the embodiments of the present disclosure, a magnitude change trend of compactness and a refractive index is the same as a strength change trend of the compact degree of molecules or atoms in the film layer. Therefore, when the magnitude relationship of compactness of two film layers is described, even if only the magnitude relationship of compactness between multiple film layers or compactness change law of a single film layer is mentioned, the magnitude relationship or change law can also be replaced by the description of a refractive index.

In at least one embodiment of the present disclosure, the material composition of at least a portion of the pixel defining layer 330 (the portion with increased compactness or refractive index) and the first packaging layer 410 may be the same or different, and may be selected according to actual requirements. For example, material composition of at least a portion of the pixel defining layer 330 is the same as that of the first packaging layer 410. In this case, different film layers made of the same material may have different compactness or refractive indexes by controlling process conditions of the film layer, such as a device power when the film layer is deposited, a deposition process type (such as chemical vapor deposition and atomic layer deposition), etc.

In a display panel, some functional film layers in the light-emitting unit are formed by evaporation, and there are multiple functional film layers in each light-emitting unit, and the material compositions of some functional film layers (such as the light-emitting layer) in the light-emitting units emitting different light rays are different. Therefore, when evaporating these functional film layers through a mask plate (such as a fine mask plate), multiple alignments are required. In order to solve the position offset problem caused by alignment accuracy errors, sufficient space (and a safety margin related to an alignment error) needs to be reserved between different light-emitting units to ensure that the position of the actual light-emitting area of the light-emitting unit can have a certain overlap rate with the designed position (a design area), which is equivalent to compressing the design area of the light-emitting area of the light-emitting unit, which not only limits a light-emitting area of the light-emitting unit, but also prevents an arrangement density of the light-emitting unit from being further increased, thereby making it difficult to further increase PPI (a pixel density) of the display panel.

In the embodiments of the present disclosure, an isolation structure is provided at the gap between the light-emitting units to separate the functional film layers of adjacent light-emitting units. Thus, in the evaporation process of the functional film layer, it is only necessary to perform evaporation on the entire display panel without the need to prepare the functional film layer of each light-emitting unit separately with the aid of a mask plate. This process does not need to consider the positioning accuracy during evaporation, so that the gap between the light-emitting units can be designed to be smaller in size to increase PPI (the principle of which can be found with reference to the relevant descriptions in the following embodiments related to FIGS. 13A to 13I).

It is to be noted that when preparing the light-emitting units through the isolation structure, because the light-emitting units are prepared in batches according to different light-emitting colors, after the preparation of the previous batch of light-emitting units is completed, a packaging structure (the first packaging layer below) will be formed thereon for protection, so as to reduce the damage caused to the previous batch of light-emitting units by the preparation process when preparing the next batch of light-emitting units. Accordingly, the packaging structure is also formed by multiple times, and a packaging effect of the packaging structure will directly affect preparation yield of the light-emitting units. In the process of forming the packaging structure, the setting of the isolation structure will affect the film forming quality of some areas of the packaging structure. As such, in a process of etching the first packaging layer, over-etching is likely to occur to damage the pixel defining layer.

Relevant contents of the isolation structure have been described in patent documents such as CN118251982A, 202410864269.8, PCT/CN2024/098407, PCT/CN2024/102783, PCT/CN2024/098217, PCT/CN2024/100935, PCT/CN2024/102785, PCT/CN2024/099419, PCT/CN2024/099072 and CN116685174A, which are listed here for reference.

In at least one embodiment of the present disclosure, as shown in FIGS. 1 to 4, the display panel 10 may further include a plurality of light-emitting units 200 located in a display region 11, and the pixel defining layer 330 includes a plurality of pixel openings 302, and the light-emitting units 200 are confined in the pixel openings 302. The light-emitting unit 200 includes a first electrode 210, a light-emitting functional layer 220, and a second electrode 230 sequentially stacked on the substrate 100, the first electrode 210 is located between the pixel defining layer 330 and the substrate 100, the pixel opening 302 exposes a portion of the first electrode 210, and the light-emitting functional layer 220 and the second electrode 230 cover the pixel opening 302 and extend to a side of the pixel defining layer 330 away from the substrate 100. The pixel opening 302 defines an effective region of the first electrode 210, which corresponds to an effective light-emitting region of the light-emitting unit 200, so that the pixel openings 302 actually defines a light-emitting region (e.g., position, area, etc.) of the light-emitting units 200 (or sub-pixels).

In the above-mentioned display panel, the pixel defining layer 330 covers the first electrode 210 under the pixel defining layer 330, and has an upper surface used to carry the second electrode 230. Therefore, film uniformity of the pixel defining layer 330 will directly affect film forming quality of the second electrode 230, and if the pixel defining layer 330 is over-etched, the first electrode 210 will be directly caused to be damaged.

In the embodiments of the present disclosure, a specific structural design of the light-emitting unit 200 is not restricted. For example, as shown in FIG. 3, the light-emitting functional layer 220 may further include a light-emitting layer 222 and a second functional layer 223, and the first functional layer 221, the light-emitting layer 222 and the second functional layer 223 are sequentially stacked on the first electrode 210. The first functional layer 221 may include a hole injection layer, a hole transport layer, an electron blocking layer, etc. The second functional layer 223 may include an electron injection layer, an electron transport layer, a hole blocking layer, etc. It is to be noted that one or more light-emitting layers 222 may be provided in the light-emitting unit 200. In a case where multiple light-emitting layers 222 are provided, the light-emitting unit 200 may have a higher light output efficiency.

For example, in at least one embodiment of the present disclosure, the first electrode 210 may be configured as an anode, and the second electrode 230 may be configured as a cathode.

In at least one embodiment of the present disclosure, as shown in FIGS. 1 to 4, the display panel 10 may further include an isolation structure 300 located on the substrate 100, the isolation structure 300 is located between the substrate 100 and the first packaging layer 410, and includes a plurality of isolation openings 301 corresponding to the pixel openings 302, and the light-emitting functional layer 220 and the second electrode 230 are located in the isolation openings 301. The light-emitting functional layer 220 and the second electrode 230 of the light-emitting unit 200 are prepared by the isolation structure 300, so that the light-emitting functional layer 220 (which may include a plurality of film layers) and the second electrode 230 in each light-emitting unit 200 will not be offset, thereby accurately controlling a position and a light-emitting area of the light-emitting unit 200, and the principle can be found with reference to the specific description in the embodiments related to FIGS. 13A to 13I below, which will not be redundantly described here; in addition, under this effect, a smaller space can be reserved between the light-emitting units 200, that is, a smaller gap can be provided between the light-emitting units 200, which facilitates the display panel to have a higher pixel density PPI.

In an actual process situation, the light-emitting unit 200 will be configured to have a microcavity effect (such that the color light corresponding to the light-emitting unit 200 can interfere constructively), therefore a film thickness of the light-emitting functional layer 220 of the light-emitting unit 200 (directly affecting a wavelength range of the interference constructive effect) is particularly important. In the embodiment of the present disclosure, light-emitting units 200 of different light-emitting colors are prepared separately based on the isolation structure 300, such that a thickness of each film layer of the light-emitting functional layer 220 (for example, each film layer in the first functional layer 221 and the second functional layer 223) in the light-emitting unit of each light-emitting color can be prepared separately, such that each light-emitting unit 200 can obtain the microcavity effect with a maximum effect. In addition, when the light-emitting unit 200 is configured to include a plurality of light-emitting layers 222, if the isolation structure 300 is not used to prepare the light-emitting unit 200, although the efficiency of the excitation light of the light-emitting unit 200 is increased, the increase in the thickness of the film layer will also cause the microcavity effect of the light-emitting unit 200 of some light-emitting colors to be reduced. In the case of using the isolation structure 300, the thickness of each film layer in the light-emitting unit 200 of each light-emitting color can still be precisely controlled, thereby still ensuring the microcavity effect of the light-emitting unit 200. Therefore, in a situation where the light-emitting unit 200 is configured to include a plurality of light-emitting layers 222, the effect of the isolation structure 300 in improving the light-emitting efficiency of the light-emitting unit 200 will be particularly obvious.

In the process of preparing the light-emitting unit 200 using the isolation structure 300, the first packaging layer 410 will be prepared simultaneously, the first packaging layer 410 will be formed by an etching process, and the isolation structure 300 will affect the film-forming quality of a part of the first packaging layer 410 (for example, the area adjacent to the support portion and the crown portion described below in the first packaging layer 410). In this area, the first packaging layer 410 is easily etched, such that the pixel defining layer 330 below is easily etched prematurely. If the pixel defining layer 330 is etched to a large extent, it will affect the film-forming quality of the second electrode 230 formed subsequently, and even in a case where the pixel defining layer 330 is etched through, the first electrode 210 is caused to be etched and damaged. In the above solution of the present disclosure, the above problem can be solved by increasing compactness of the pixel defining layer 330 to enhance etching resistance of the pixel defining layer 330. The formation process of the first packaging layer 410 in the above process can be found with reference to the specific description in the embodiments related to the following FIGS. 13A to 13I, which will not be redundantly described here.

In the embodiments of the present disclosure, compactness or a refractive index of an entirety or a portion of the pixel defining layer can be increased according to different requirements, and in a case where compactness or a refractive index of a portion is increased, compactness or a refractive index of an upper portion, a lower portion, or a middle portion of the pixel defining layer can be increased. The specific structure of the display panel under the above different options is described below through different embodiments.

In some embodiments of the present disclosure, as shown in FIGS. 3 to 5A, compactness of the pixel defining layer 330 is greater than compactness of the first packaging layer 410, or a refractive index of the pixel defining layer 330 is greater than a refractive index of the first packaging layer 410, that is, compactness of any portion of the pixel defining layer 330 is greater than compactness of any portion of the first packaging layer 410, and a refractive index of any portion of the pixel defining layer 330 is greater than a refractive index of any portion of the first packaging layer 410.

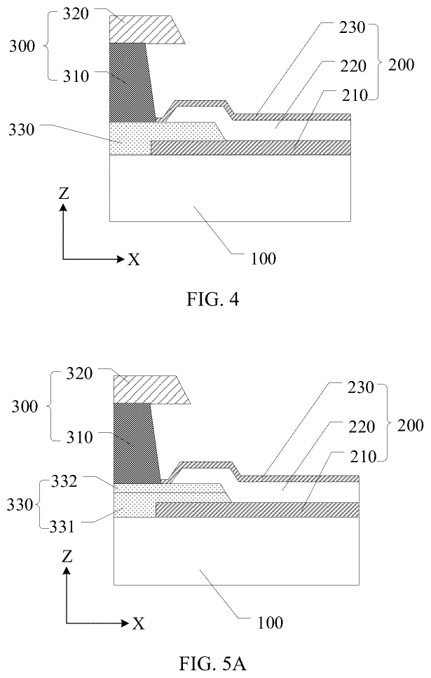

For example, in some examples, as shown in FIGS. 3 and 4, the pixel defining layer 330 is a single-layer structure. As such, the structural strength of the pixel defining layer 330 can be ensured to avoid risks such as interface separation in a multi-layer design.

For example, in some examples, as shown in FIG. 3 and FIG. 5A, the pixel defining layer 330 includes a first sub-defining layer 331 and a second sub-defining layer 332 which are stacked, and the first sub-defining layer 331 and the second sub-defining layer 332 have the same compactness. As such, the material selection range of the pixel defining layer 330 can be increased, for example, the two first sub-defining layers 331 and the second sub-defining layer 332 can be formed using different materials to be used in different process requirements (such as different shapes of the sidewalls of the pixel opening 302 described below).

In some other embodiments of the present disclosure, along a thickness direction of the pixel defining layer 330, compactness of a side of the pixel defining layer 330 close to the first packaging layer 410 is greater than compactness of the first packaging layer 410, and compactness of a side of the pixel defining layer 330 close to the first packaging layer 410 is greater than compactness of a side of the pixel defining layer 330 away from the first packaging layer 410; or, along a thickness direction of the pixel defining layer 330, a refractive index of a side of the pixel defining layer 330 close to the first packaging layer 410 is greater than a refractive index of the first packaging layer 410, and a refractive index of a side of the pixel defining layer 330 close to the first packaging layer 410 is greater than a refractive index of the first packaging layer 410. As exemplarily shown in FIG. 3 and FIGS. 5A to 5B, along the Z-axis direction perpendicular to the plane in which the substrate 100 is located (equivalent to the thickness direction of the pixel defining layer 330), compactness (or a refractive index) of a portion of the pixel defining layer 330 away from the substrate 100 (the side close to the first packaging layer 410, such as the second sub-defining layer 332 or the third sub-defining layer 333) is greater than compactness (or a refractive index) of the first packaging layer 410, and compactness (or a refractive index) of a portion of the pixel defining layer 330 that is away from the substrate 100 (the side close to the first packaging layer 410) is greater than compactness (or a refractive index) of the other portions of the pixel defining layer 330 (the side away from the first packaging layer 410, such as the first sub-defining layer 331 or the second sub-defining layer 332). As such, compactness (or a refractive index) of the top portion of the pixel defining layer 330 can be increased, thereby further reducing a degree to which the pixel defining layer 330 is etched during an etching process of the first packaging layer 410, so as to improve integrity of the pixel defining layer 330, thereby improving film continuity of the second electrode 230 formed on the pixel defining layer 330.

For example, the pixel defining layer 330 includes at least two sub-defining layers sequentially stacked on the substrate 100, compactness of the sub-defining layer close to the first packaging layer 410 is greater than compactness of the sub-defining layer away from the first packaging layer 410, or a refractive index of the sub-defining layer close to the first packaging layer 410 is greater than a refractive index of the sub-defining layer away from the first packaging layer 410. As exemplarily shown in FIG. 5A, along the thickness direction of the pixel defining layer 330, the pixel defining layer 330 includes at least two first sub-defining layers 331 and a second sub-defining layer 332 sequentially stacked on the substrate 100, and compactness (or a refractive index) of the second sub-defining layer 332 closest to the first packaging layer 410 is greater than compactness (or a refractive index) of the first sub-defining layer 331; or, as shown in FIG. 5B, along the thickness direction of the pixel defining layer 330, the pixel defining layer 330 includes at least two first sub-defining layers 331, a second sub-defining layer 332 and a third sub-defining layer 333 sequentially stacked on the substrate 100, and compactness (or a refractive index) of the third sub-defining layer 333 closest to the first packaging layer 410 is greater than compactness (or a refractive index) of the first sub-defining layer 331 and the second sub-defining layer 332. When the pixel defining layer 330 is formed by a plurality of sub-defining layers, the difficulty of preparing the pixel defining layer 330 and the selection of materials can be reduced, thereby facilitating the control of the preparing process cost of the display panel.

In an embodiment of the present disclosure, when describing the relative positions of each sub-defining layer, if the display panel includes a first packaging layer 410, the sub-defining layer that is closer to the substrate is farther away from the first packaging layer 410, and correspondingly, the sub-defining layer that is farther away from the substrate is closer to the first packaging layer 410.

For example, in some examples, as shown in FIG. 5A, compactness (or a refractive index) of the first sub-defining layer 331 closest to the substrate 100 is greater than or equal to compactness (or a refractive index) of the first packaging layer 410. As such, when the second sub-defining layer 332 farthest from the substrate 100 has sufficient compactness (or a refractive index) to resist etching, compactness (or a refractive index) requirements of other first sub-defining layers 331 of the pixel defining layer 330 can be reduced, and even the first packaging layer 410 and the first sub-defining layer 331 closest to the substrate 100 can be prepared using the same or similar materials, which facilitates reducing a preparing process cost of the display panel.

For example, in other examples, the pixel defining layer 330 includes at least three sub-defining layers stacked sequentially on the substrate 100, and along a direction away from the substrate 100, compactness of the sub-defining layer gradually increases or a refractive index of the sub-defining layer gradually increases. As exemplarily shown in FIG. 5B, the pixel defining layer 330 includes three first sub-defining layers 331, second sub-defining layers 332, and third sub-defining layers 333 stacked sequentially on the substrate 100, and the first sub-defining layer 331, the second sub-defining layer 332, and the third sub-defining layer 333 are sequentially away from the substrate 100, and compactness (or a refractive index) of the first sub-defining layer 331, the second sub-defining layer 332, and the third sub-defining layer 333 increases sequentially. As such, the difficulty of the preparation process of the pixel defining layer 330 can be reduced. For example, the first sub-defining layer 331, the second sub-defining layer 332, and the third sub-defining layer 333 can be directly formed using different materials or different processes to simplify a preparation process of the display panel.

In other embodiments of the present disclosure, along a thickness direction of the pixel defining layer 330, compactness of a middle portion of the pixel defining layer 330 is greater than compactness of the first packaging layer 410, and compactness of the middle portion of the pixel defining layer 330 is greater than compactness of other portions of the pixel defining layer 330; or, a refractive index of a middle portion of the pixel defining layer 330 is greater than a refractive index of the first packaging layer 410, and a refractive index of the middle portion of the pixel defining layer 330 is greater than a refractive index of other portions of the pixel defining layer. As exemplarily shown in FIGS. 3 and 5B, the pixel defining layer 330 includes three first sub-defining layers 331, second sub-defining layers 332, and third sub-defining layers 333 which are sequentially stacked on the substrate 100, and the first sub-defining layer 331, the second sub-defining layer 332, and the third sub-defining layer 333 are sequentially away from the substrate 100, and compactness (or a refractive index) of the second sub-defining layer 332 (the middle portion of the pixel defining layer 330) is greater than compactness (or a refractive index) of the first packaging layer 410, and compactness (or a refractive index) of the second sub-defining layer 332 is greater than compactness (or a refractive index) of the first sub-defining layer 331 and the third sub-defining layer 333. As such, in the etching process of the first packaging layer 410, a degree to which the pixel defining layer 330 is etched can be reduced to have a certain integrity, while reducing the risk of the pixel defining layer 330 being etched through, thereby improving quality of a structure formed on the pixel defining layer 330 (such as film layer continuity of the second electrode 230 described below) and integrity of a structure under the pixel defining layer 330, such as the first electrode 210.

For example, as shown in FIG. 5B, in a case where the pixel defining layer 330 is formed by a plurality of layers of a first sub-defining layer 331, a second sub-defining layer 332, and a third sub-defining layer 333, a difficulty in preparing the pixel defining layer 330 and material selection can be reduced. For example, the first sub-defining layer 331, the second sub-defining layer 332, and the third sub-defining layer 333 can be directly formed using different materials or different processes, which is beneficial for controlling a preparation process cost of the display panel.

For example, in some examples, as shown in FIG. 3 and FIG. 5B, in a case where compactness (or a refractive index) of a middle portion of the pixel defining layer 330, such as the second sub-defining layer 332, is greater than compactness (or a refractive index) of the first packaging layer 410, compactness (or a refractive index) of the third sub-defining layer 333 which is farthest from the substrate 100 can be less than or equal to compactness (or a refractive index) of the first packaging layer 410. As such, the portion of the sidewall of the pixel defining layer 330 far from the substrate 100 can be made smoother relative to the surface where the substrate 100 is located, so as to improve continuity of the film layer formed on the sidewall of the pixel defining layer 330.

For example, in some examples, as shown in FIG. 3 and FIG. 5B, in a case where compactness (or a refractive index) of a middle portion of the pixel defining layer 330, such as the second sub-defining layer 332, is greater than compactness (or a refractive index) of the first packaging layer 410, compactness (or a refractive index) of the third sub-defining layer 333 which is farthest from the substrate 100 is equal to the compactness (or a refractive index) of the first sub-defining layer 331 which is closest to the substrate 100, or compactness (or a refractive index) of the first sub-defining layer 331 which is closest to the substrate 100 is less than or equal to compactness (or a refractive index) of the first packaging layer 410. As such, in the process of the first packaging layer 410, the etching resistance of the entire pixel defining layer 330 can be further improved to reduce the etching damage of the pixel defining layer 330. In addition, the design of the first sub-defining layer 331 can cause a portion of the side wall of the pixel defining layer 330 close to the substrate 100 to be gentler relative to a plane in which the substrate 100 is located, so as to improve continuity of the film layer formed on the side wall of the pixel defining layer 330.

For example, in some examples, compactness (or a refractive index) of the first sub-defining layer 331 can be set to be equal to compactness (or a refractive index) of the first packaging layer 410, so that compactness (or a refractive index) of the entire pixel defining layer 330 is greater than compactness (or a refractive index) of the first packaging layer 410, thereby further improving the etching resistance of the pixel defining layer 330 in the process of the first packaging layer 410.

In other embodiments of the present disclosure, along a thickness direction of the pixel defining layer 330, compactness of a side of the pixel defining layer 330 close to the substrate 100 is greater than compactness of the first packaging layer 410, and compactness of a side of the pixel defining layer 330 close to the substrate is greater than compactness of other portions of the pixel defining layer 330; or, along a thickness direction of the pixel defining layer 330, a refractive index of a side of the pixel defining layer 330 close to the substrate is greater than a refractive index of the first packaging layer 410, and a refractive index of a portion of the pixel defining layer 330 close to the substrate is greater than a refractive index of other portions of the pixel defining layer 330. As exemplarily shown in FIG. 3 and FIG. 5A, along a Z-axis direction perpendicular to the plane in which the substrate 100 is located (which is equivalent to a thickness direction of the pixel defining layer 330), the pixel defining layer 330 includes a first sub-defining layer 331 and a second sub-defining layer 332 sequentially stacked on the substrate 100, and compactness of the first sub-defining layer 331 is greater than compactness (or a refractive index) of the first packaging layer 410 and greater than compactness (or a refractive index) of the second sub-defining layer 332. As such, a risk of the pixel defining layer 330 being etched through during an etching process of the first packaging layer 410 can be further reduced, thereby further protecting integrity of the structure below the pixel defining layer 330; in addition, this design facilitates increasing a degree to which the side wall of the pixel defining layer 330 (which is also equivalent to the side wall of the pixel opening 302) is inclined (with a slope caused to be gentler) to improve quality of a structure formed on the pixel defining layer 330 (for example, film layer continuity of the second electrode 230 described below).

For example, in some examples, in a case where the pixel defining layer includes at least two sub-defining layers stacked sequentially on the substrate, compactness of the sub-defining layer close to the substrate is greater than compactness of other sub-defining layers, or a refractive index of the sub-defining layer close to the substrate is greater than a refractive index of other sub-defining layers. As exemplarily shown in FIG. 3 and FIG. 5B, the pixel defining layer 330 includes three layers of a first sub-defining layer 331, a second sub-defining layer 332 and a third sub-defining layer 333 stacked sequentially on the substrate 100, and the first sub-defining layers 331, second sub-defining layers 332 and third sub-defining layers 333 are sequentially away from the substrate 100, and compactness (or a refractive index) of the first sub-defining layer 331 farthest from the first packaging layer 410 is greater than compactness (or a refractive index) of each of the second sub-defining layers 332 and the third sub-defining layers 333. In a case where the pixel defining layer 330 is formed by a plurality of layers of a first sub-defining layer 331 and a second sub-defining layer 332, the difficulty in preparing the pixel defining layer 330 and material selection of can be reduced, thereby facilitating control of a preparing process cost of the display panel.

For example, in some examples, compactness of the sub-defining layer close to the first packaging layer is greater than or equal to compactness of the first packaging layer, or a refractive index of the sub-defining layer close to the first packaging layer is greater than or equal to a refractive index of the first packaging layer. As exemplarily shown in FIG. 3 and FIG. 5A, compactness (or a refractive index) of the second sub-defining layer 332 is greater than or equal to compactness (or a refractive index) of the first packaging layer 410; or, as shown in FIG. 3 and FIG. 5B, compactness (or a refractive index) of the third sub-defining layer 333 is greater than or equal to compactness (or a refractive index) of the first packaging layer 410.

For example, in some examples, as shown in FIG. 3 and FIG. 5B, the pixel defining layer 330 includes at least three layers of a first sub-defining layer 331, a second sub-defining layer 332 and a third sub-defining layer 333 stacked sequentially on the substrate 100, and compactness (or a refractive index) of each of the first sub-defining layer 331, the second sub-defining layer 332 and the third sub-defining layer 333 gradually decreases along a direction away from the substrate 100. As such, in a process of the first packaging layer 410, the side wall of the pixel defining layer 330 can be made gentler, so as to improve continuity of a film layer formed on the side wall of the pixel defining layer 330.

In at least one embodiment of the present disclosure, the material of the pixel defining layer 330 and the first packaging layer 410 may include at least one of silicon nitride, silicon oxide and silicon oxynitride.

It is to be noted that in the embodiments of the present disclosure, a shape of the sidewall of the pixel defining layer 330 (equivalent to the side surface of the pixel opening) will affect quality of the subsequent deposited film layer. Therefore, how to control a shape of the sidewall to guarantee quality of the deposited film layer is particularly important in a preparing process of the display panel. In the following, in conjunction with specific embodiments, a setting manner of a shape of the sidewall of the pixel defining layer 330 in the display panel is described.

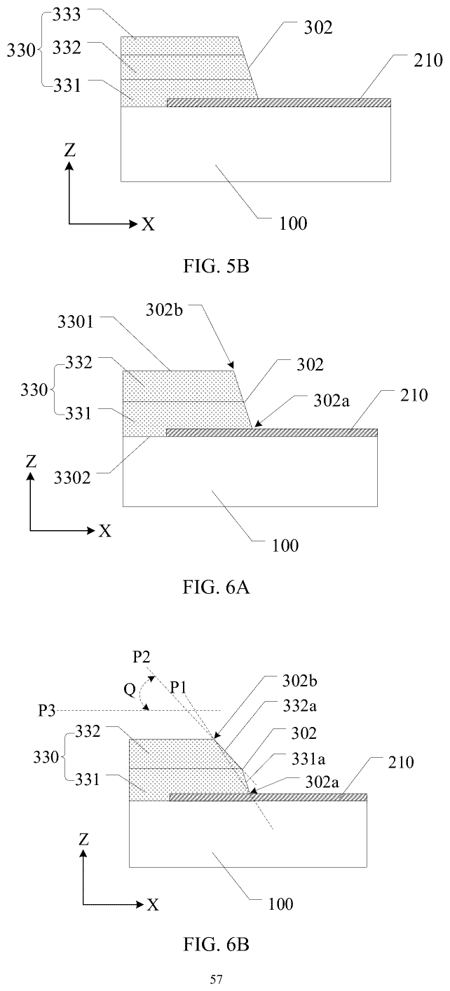

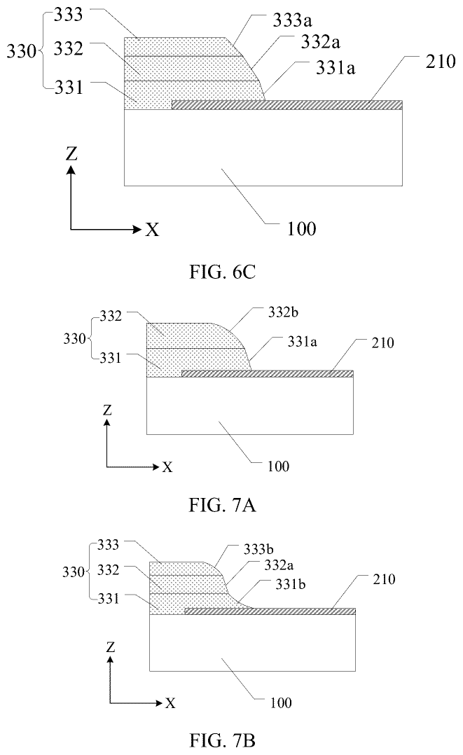

At least one embodiment of the present disclosure provides a display panel, as shown in FIGS. 1, 2, 3 and 6A, the display panel 10 includes a substrate 100 and a pixel defining layer 330 located on the substrate 100, a surface of the pixel defining layer 330 away from the substrate 100 is a first surface 3301, a surface of the pixel defining layer 330 close to the substrate 100 is a second surface 3302, an orthogonal projection, located on the substrate 100, of the first surface 3301 is located within an orthogonal projection, located on the substrate 100, of the second surface 3302, the pixel defining layer 330 includes a side wall that connects the first surface 3301 and the second surface 3302 and that is inclined relative to a plane in which the substrate 100 is located, that is, the side wall intersects and is not perpendicular to the plane in which the substrate 100 is located. In addition, the pixel defining layer 330 includes at least two sub-defining layers stacked on the substrate 100, such as a first sub-defining layer 331 and a second sub-defining layer 332 (FIG. 6A shows two cases), side walls of the first sub-defining layer 331 and the second sub-defining layer 332 participate in forming a side wall of the pixel defining layer 330, and angles at which the side walls of the at least two sub-defining layers are inclined relative to the plane in which the substrate 100 is located may be the same or different, that is, a degree to which the side wall of each sub-defining layer is inclined can be individually adjusted, thereby controlling a shape of the side wall of the pixel defining layer 330. As such, a degree to which each sub-defining layer of the pixel defining layer 330 is etched can be controlled to individually adjust a degree to which the side wall of each sub-defining layer is inclined, thereby controlling a specific shape of the side wall of the pixel defining layer 330, for example, angles at which the side walls of the at least two sub-defining layers are inclined relative to a plane in which the substrate 100 is located may be the same or different, thereby ensuring film formation quality of a film layer (such as the second electrode described below) on the pixel defining layer.

It is to be noted that a specific providing manner of the pixel defining layer 330 in the display panel, as well as other structures that may be included in the display panel in a further design, such as the first packaging layer, the light-emitting unit, the isolation structure, etc., can be found with reference to the relevant descriptions in the aforementioned embodiments, and will not be redundantly described here.

For example, as shown in FIG. 3 and FIG. 6A, the sidewall of the pixel defining layer 330 surrounds the pixel opening 302, and the sidewall of the pixel defining layer 330 includes a first edge 302a (close to the substrate 100 side) intersecting with the second surface 3302 and a second edge 302b (away from the substrate 100 side) intersecting with the first surface 3301, and the plane defined by the first edge 302a and the second edge 302b intersects and is not perpendicular to the plane in which the substrate 100 is located. As such, a film layer (such as the second electrode 230 mentioned in the above embodiment) located on the pixel defining layer 330 can be guaranteed to be continuous on the sidewall of the pixel defining layer 330, thereby improving yield of the display panel.

For example, an angle between the plane P1 defined by the first edge 302a and the second edge 302b and the plane in which the substrate 100 is located is not greater than 45 degrees. When this value is met, the quality of the film layer on the sidewall of the pixel defining layer 330 can be guaranteed.

In some embodiments of the present disclosure, as shown in FIGS. 6A to 6C and FIGS. 7A and 7C, the sidewall of the pixel defining layer 330 is a continuous surface. As such, the continuity of the film layer (such as the light-emitting functional layer 220 and the second electrode 230) formed at the pixel opening 302 on the sidewall can be improved to ensure the display effect of the display panel.

In some examples, as shown in FIG. 6A, in a case where the sidewall of the pixel defining layer 330 is a continuous surface, along a direction perpendicular to the plane in which the substrate 100 is located (eg, the direction of the Z axis), a sectional shape of the sidewall of the pixel defining layer 330 is a straight line segment.

In other examples, as shown in FIG. 6B (or FIG. 6C), the pixel defining layer 330 includes at least two sub-defining layers stacked on the substrate 100, and angles at which the side walls of the at least two sub-defining layers are inclined relative to a plane in which the substrate 100 is located may be the same or different. As such, by designing the pixel defining layer 330 to be composed of at least two sub-defining layers, the structural parameters (such as compactness, etc.) of different portions of the pixel defining layer 330 can be controlled, such that a degree to which different portions of the pixel defining layer 330 are etched can be controlled and a specific shape of the side wall can be controlled to ensure film formation quality of the film layer (such as the second electrode 230) on the pixel defining layer.

In a section perpendicular to a plane in which the substrate 100 is located, an angle between a straight line in which the side wall of the sub-defining layer is located and the plane in which the substrate 100 is located is not greater than 45 degrees. For example, the angle is not greater than 40 degrees, such as 39 degrees, 37 degrees, 35 degrees, 32 degrees, and 30 degrees. As such, the smaller the angle, the more continuity of a film layer (such as the second electrode described below) located on the pixel defining layer 330 on the side wall of the pixel defining layer 330 can be improved, thereby improving yield of the display panel. In addition, when this value is met, film formation quality of the film layer located on the pixel defining layer on the side wall of the pixel defining layer can be guaranteed. Specifically, in a case where a sidewall of the pixel defining layer 330 is a continuous surface, along a direction perpendicular to a plane in which the substrate 100 is located, the sectional shape of the sidewall of the pixel defining layer 330 is a line segment sequentially connected end to end by a plurality of straight line segments, such as 331a, 332a (or also including the straight line segment 333a in FIG. 6C), and an acute angles Q at which lines in which these straight line segments are located intersect with the plane in which the substrate 100 is located are different. For example, a line P2 in which a line segment (such as the straight line segment 332a) which is farther from the substrate 100 is located intersects a plane in which the substrate 100 is located (parallel to a straight line P3) at a smaller acute angle Q, that is, a slope of the line segment 332a is smaller than a slope of the line segment 331a, and a slope of the line segment 333a is smaller than a slope of the line segment 332a. For example, the acute angle Q corresponding to each of the straight line segments 331a and 332a is less than or equal to 45 degrees. As such, the second electrode 230 film layer can be deposited at a junction of the sidewall of the pixel defining layer 330 and a surface away from the substrate 100, so as to further improve continuity of the second electrode 230 at the junction.

In other examples, the structure shown in FIG. 6B (or FIG. 6C) can be modified to transform all the straight line segments therein into curved line segments, so that when the side wall of the pixel defining layer 330 is a continuous surface, along the direction perpendicular to the plane in which the substrate 100 is located, a sectional shape of the side wall of the pixel defining layer 330 is a line segment composed of multiple curved line segments connected end to end, and the multiple curved line segments have different curvatures. As such, at the intersection of the side wall of the pixel defining layer 330 and the surface away from the substrate 100, it can be facilitated to deposit the film layer (such as the light-emitting functional layer 220 and the second electrode 230) there, so as to further improve continuity of these film layers at the intersection.

In other examples, as shown in FIG. 7A, when the sidewall of the pixel defining layer 330 is a continuous surface, along the direction perpendicular to the plane in which the substrate 100 is located, the sectional shape of the sidewall of the pixel defining layer 330 is a line segment composed of a curved segment 332b and a straight segment 331a connected to each other, and the straight segment 331a is located between the curved segment 332b and the substrate 100. As such, the corner at the junction of the sidewall of the pixel defining layer 330 and the surface away from the substrate 100 is approximately rounded, thereby further improving continuity of the film layers on the pixel defining layer 330.

For example, as shown in FIG. 7A, the curved segment 332b is smoothly connected to the straight segment 331a, and the curved segment 332b is smoothly connected to a surface of the pixel defining layer 330 away from the substrate 100.

In other examples, as shown in FIG. 7B, when the sidewall of the pixel defining layer 330 is a continuous surface, along the direction perpendicular to the plane in which the substrate 100 is located, a sectional shape of the sidewall of the pixel defining layer 330 is a line segment composed of a first curved segment 331b, a straight segment 332a, and a second curved segment 333b connected to each other, and the distances from the first curved segment 331b, the straight segment 332a, and the second curved segment 333b to the substrate 100 increase sequentially. As such, a junction of the sidewall of the pixel defining layer 330 and the surface away from the substrate 100, as well as a junction of the bottom of the pixel opening 302 and the sidewall, can facilitate the deposition of film layers (such as the light-emitting functional layer 220 and the second electrode 230 described below), so as to further improve the continuity of these film layers at the two junctions.

For example, the middle portion of the first curve segment 331b is located on the side of the straight line determined by the two ends of the first curve segment 331b facing the pixel defining layer 330, that is, the first curve segment 331b presents a concave surface; the middle portion of the second curve segment 333b is located on the side of the straight line determined by the two ends of the second curve segment 333b away from the pixel defining layer 330, that is, the second curve segment 333b presents a convex surface.

For example, both of the first curve segment 331b and the second curve segment 333b are smoothly connected to the straight line segment 332a, the second curve segment 333b is smoothly connected to a surface of the pixel defining layer 330 away from the substrate 100, and a tangent line on an end of the first curve segment 331b close to the substrate 100 is parallel to the plane in which the substrate 100 is located.

In at least one embodiment of the present disclosure, as shown in FIGS. 6A to 6C and FIGS. 7A and 7C, in a case where the sidewall of the pixel defining layer 330 is a continuous surface, the pixel defining layer 330 includes at least two layers of a first sub-defining layer 331 and a second sub-defining layer 332 stacked sequentially on the substrate 100, and a side surface of each of the first sub-defining layer 331, the second sub-defining layer 332 and the third sub-defining layer 333 include straight line segments or curved line segments, that is, each straight line segment or curved line segment corresponds to a section of the side surface of the sub-defining layer. For example, as shown in FIG. 6C, straight line segments 331a, 332a and 333a correspond to side surfaces of the first sub-defining layer 331, the second sub-defining layer 332 and the third sub-defining layer 333, respectively.

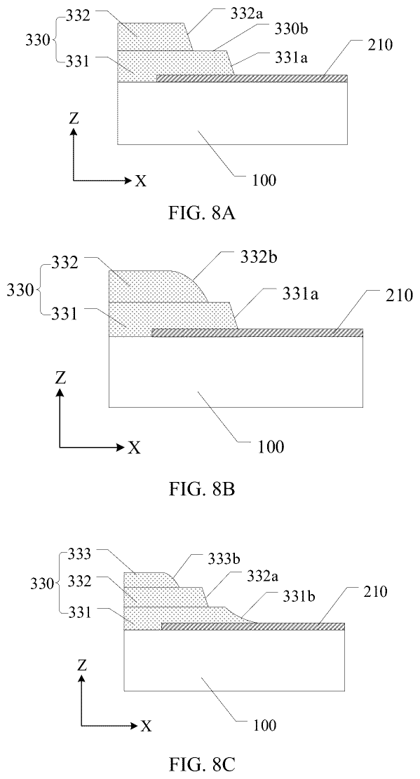

In other embodiments of the present disclosure, as shown in FIGS. 8A to 8C, a sidewall of the pixel defining layer 330 is a stepped surface. As such, continuity of the film layer (such as the light-emitting functional layer 220 and the second electrode 230) formed at the pixel opening 302 on the sidewall can be improved to ensure a display effect of the display panel.

For example, as shown in FIG. 8A, in the case where the sidewall of the pixel defining layer 330 is a stepped surface, the pixel defining layer 330 includes at least two first sub-defining layers 331 and second sub-defining layers 332 sequentially stacked on the substrate 100, and in each adjacent first sub-defining layer 331 and second sub-defining layer 332, an orthogonal projection, located on the substrate 100, of the second sub-defining layer 332 far from the substrate 100 is located within an orthogonal projection, located on the substrate 100, of the first sub-defining layer 331 close to the substrate 100, that is, a sidewall of the first sub-defining layer 331 is not directly connected to a sidewall of the second sub-defining layer 332. As such, it is convenient to prepare the pixel defining layer 330 with stepped sidewalls.

For example, as shown in FIG. 8A, along a direction perpendicular to a plane in which the substrate 100 is located, a sectional shape of a sidewall of each of the first sub-defining layer 331 and the second sub-defining layer 332 is a first line segment 331a, 332a. For example, the first line segment 331a is disconnected from the first line segment 332a. For example, along the direction perpendicular to the plane in which the substrate 100 is located, a sectional shape of a portion exposed relative to the second sub-defining layer 332 of a surface of the first sub-defining layer 331 away from the substrate 100 is a second line segment 330b, and a sectional shape of a sidewall of the pixel defining layer is a line segment sequentially connected by the first line segment 331a, the second line segment 330b and the first line segment 332a.

In some examples, as shown in FIG. 8A, in a case where a sidewall of the pixel defining layer 330 is a stepped surface, along a direction perpendicular to the plane in which the substrate 100 is located, a side surface of each of the first sub-defining layer 331 and the second sub-defining layer 332 has a sectional shape consisting of straight line segments that are disconnected at ends and not directly connected.

In some examples, as shown in FIG. 8A, one of the first sub-defining layer 331 and the second sub-defining layer 332 farther from the substrate 100 has a side surface that intersects with the plane in which the substrate 100 is located at a smaller acute angle, that is, a slope of the second sub-defining layer 332 is smaller than a slope of the first sub-defining layer 331. As such, deposition of a film layer on the top of the side wall of the pixel defining layer 330, thereby further improving continuity of a film layer on the side wall of the pixel defining layer 330.

In other examples, as shown in FIG. 8B, when the sidewall of the pixel defining layer 330 is a stepped surface, along a direction perpendicular to the plane in which the substrate 100 is located, a sectional shape of the side surface of the second sub-defining layer 332 farthest from the substrate 100 is a curved segment 332b, and a sectional shape of the side surface of the other first sub-defining layers 331 is a straight segment 331a. As such, the corner at the junction of the sidewall of the pixel defining layer 330 and the surface away from the substrate 100 is approximately rounded, thereby further improving the continuity of the second electrode on the pixel defining layer 330.

For example, as shown in FIG. 8B, the side surface of the second sub-defining layer 332 farthest from the substrate 100 is smoothly connected to the surface of the pixel defining layer 330 away from the substrate 100, that is, a tangent line at the edge of the side surface of the second sub-defining layer 332 farthest from the substrate 100 is parallel to the surface of the pixel defining layer 330 away from the substrate 100.

In other examples, as shown in FIG. 8C, in a case where the side wall of the pixel defining layer 330 is a stepped surface, along a direction perpendicular to the plane in which the substrate 100 is located, a sectional shapes of the side surfaces of the first sub-defining layer 331 closest to the substrate 100 and the third sub-defining layer 333 farthest from the substrate 100 are curved segments 331b and 333b respectively. For the first sub-defining layer 331 closest to the substrate 100, a middle portion of the curved segment 331b is located on a side of a straight line determined by both ends of the curved segment facing the pixel defining layer 330, that is, the curved segment 331b appears as a concave surface; for the third sub-defining layer 333 farthest from the substrate 100, a middle portion of the curved segment 333b is located on a side of a straight line determined by both ends of the curved segment away from the pixel defining layer 330, that is, the curved segment 333b appears as a convex surface. As such, a junction between a side wall of the pixel defining layer 330 and a surface of the pixel defining layer 330 away from the substrate 100, as well as a junction between a bottom and a side wall of the pixel opening 302, can facilitate the deposition of film layers (such as the light-emitting functional layer 220 and the second electrode 230 described below), so as to further improve continuity of the second electrode at the two junctions.

For example, as shown in FIG. 8C, the side surface of the third sub-defining layer 333 farthest from the substrate 100 is smoothly connected to the surface of the pixel defining layer 330 away from the substrate 100, and the tangent of the end of the side surface of the first sub-defining layer 331 closest to the substrate 100 close to the substrate 100 is parallel to the surface where the substrate 100 is located.

In the embodiment of the present disclosure, the surface roughness on the sidewall of the pixel defining layer 330 may be less than or equal to 0.05 micrometers. For example, the sidewall of the pixel defining layer 330 has defect structures such as depressions, protrusions, and burrs, and the thickness, diameter, and other dimensions of these defect structures are less than or equal to 0.05 micrometers. As such, the problem that the surface roughness of the pixel defining layer 330 is too large and causes wrinkles on the second electrode can be avoided, so that the impedance of the second electrode can be reduced. For example, a surface roughness on the sidewall of the pixel defining layer 330 may be 0 μm, 0.01 μm, 0.02 μm, 0.03 μm, 0.04 μm, 0.05 μm, etc.

In at least one embodiment of the present disclosure, referring to FIG. 5A again, along a direction away from the substrate 100, the pixel defining layer 330 includes a first sub-defining layer 331 and a second sub-defining layer 332 which are sequentially stacked on the substrate 100, and the first sub-defining layer 331 and the second sub-defining layer 332 have different compactness (or different refractive indexes). For example, compactness of the second sub-defining layer 332 is greater than compactness of the first sub-defining layer 331; or, a refractive index of the second sub-defining layer 332 is greater than a refractive index of the first sub-defining layer 331; or, under the same etching condition, an etching rate of the second sub-defining layer 332 is lower than an etching rate of the first sub-defining layer 331. As such, a degree to which the pixel defining layer 330 is etched in an etching process of the first packaging layer 410 can be further reduced to improve integrity of the pixel defining layer 330, thereby improving continuity of a film layer formed on the pixel defining layer 330.

For example, the material of the first sub-defining layer 331 or the second sub-defining layer 332 includes at least one of silicon nitride, silicon oxide and silicon oxynitride.

In at least one embodiment of the present disclosure, the thickness of the pixel defining layer 330 is 2000 angstroms to 5000 angstroms, for example, 2000 angstroms, 2500 angstroms, 3000 angstroms, 3500 angstroms, 4000 angstroms, 4500 angstroms, 5000 angstroms, etc.

In at least one embodiment of the present disclosure, referring to FIG. 5A again, the pixel defining layer 330 includes a first sub-defining layer 331 and a second sub-defining layer 332 which are sequentially stacked on the substrate 100, and the first sub-defining layer 331 may be thicker than the second sub-defining layer 332. For example, the thickness of the first sub-defining layer 331 closest to the substrate 100 is 2000-3000 angstroms, such as further 2000 angstroms, 2200 angstroms, 2400 angstroms, 2500 angstroms, 2600 angstroms, 2800 angstroms, 3000 angstroms, etc.; the thickness of the second sub-defining layer 332 farthest from the substrate 100 is 500-1000 angstroms, such as further 500 angstroms, 600 angstroms, 700 angstroms, 800 angstroms, 900 angstroms, 1000 angstroms, etc.

In at least one embodiment of the present disclosure, referring to FIG. 3B and FIG. 5B again, the display panel may further include a planar layer 110, which is located between the pixel defining layer 330 and the substrate 100 and is an organic film layer, and the material composition of the first sub-defining layer 331 closest to the substrate 100 includes silicon nitride. The bonding strength between silicon nitride and the organic film layer is higher, so that the bonding strength between the pixel defining layer 330 and the planar layer 110 can be increased, and the risk of separation of an interface agent from the film layer can be reduced, so as to improve reliability of the display panel.

For example, the substrate 100 may include a substrate and a driving circuit layer located on the substrate, the driving circuit layer includes a plurality of pixel driving circuits located in the display region, and the display function layer is located on the driving circuit layer. For example, the pixel driving circuit may include a plurality of transistors TFT, capacitors, etc., for example, formed in various forms such as 2T1C (i.e., 2 transistors (TFT) and 1 capacitor (C)), 3T1C or 7T1C. The pixel driving circuit is connected to the light-emitting unit 200 to control the switching state and the light-emitting brightness of the light-emitting unit 200. In the embodiment of the present disclosure, the positional relationship between the isolation structure 300 and the driving circuit is not limited, and can be selected according to actual process requirements. For example, as a setting method, referring to FIG. 3 again, an orthogonal projection, located on the substrate 100, of the driving circuit partially overlaps with an orthogonal projection, located on the substrate 100, of the isolation structure 300; or, in other settings, an orthogonal projection, located on the substrate 100, of the driving circuit does not overlap with an orthogonal projection, located on the substrate 100, of the isolation structure 300.

In at least one embodiment of the present disclosure, referring to FIG. 3 again, the display panel includes a plurality of light-emitting units 200, and the pixel opening 302 of the pixel defining layer 330 confines the light-emitting unit 200. The specific structure of the light-emitting unit 200 and the arrangement relationship between the light-emitting unit 200 and the pixel defining layer 330 can be found with reference to the relevant description in the aforementioned embodiment, and will not be redundantly described here. For example, the first electrode 210 of the light-emitting unit 200 is located on the side of the flat layer 110 away from the substrate 100, and the flat layer 110 is used to flatten the driving circuit layer to guarantee flatness of the first electrode 210.

In at least one embodiment of the present disclosure, the display panel may further include an isolation structure 300. The setting relationship between the isolation structure 300 and the light-emitting unit 200 can be found with reference to the relevant description in the aforementioned embodiment and will not be redundantly described here. In the embodiment of the present disclosure, in a case where it is possible to ensure that the isolation structure 300 isolates the light-emitting functional layer in the light-emitting unit 200 and the preparation of the light-emitting unit can be assisted, a specific design of the isolation structure 300 is not limited and can be designed according to actual process requirements. Below, several design structures of the isolation structure 300 are described through several specific embodiments.

In at least one embodiment of the present disclosure, as shown in FIGS. 3 and 4, the isolation structure 300 is located between the pixel defining layer 330 and the first packaging layer 410, and includes a support portion 310 and a crown portion 320, the support portion 310 is located between the crown portion 320 and the substrate 100, and an orthogonal projection, located on the substrate 100, of the support portion 310 is located within an orthogonal projection, located on the substrate 100, of the crown portion 320, that is, the isolation structure 300 as a whole will appear to be wide at the top and narrow at the bottom, so that when a portion of the film layer (for example, the light-emitting functional layer 220) in the light-emitting unit 200 is evaporated, it is disconnected at an edge of the isolation structure 300 to reduce the risk of crosstalk between adjacent light-emitting units 200.

In some embodiments of the present disclosure, a main structure of the isolation structure 300 may tend to be made of a conductive material to reduce a voltage when the second electrode 230 is driven. For example, as shown in FIG. 3 and FIG. 4, the support portion 310 is a conductive structure, and the second electrode 230 is electrically connected to a side surface of the support portion 310. As such, the support portion 310 can be used to assist in connecting the second electrode 230, and because the support portion 310 is located at a gap of the light-emitting unit 200, it can have a higher design thickness (greater than a thickness of the second electrode 230) and can be made of a high conductivity material, so that when connected to the second electrode 230, a voltage drop problem generated on the second electrode 230 when the light-emitting unit 200 is driven can be reduced.

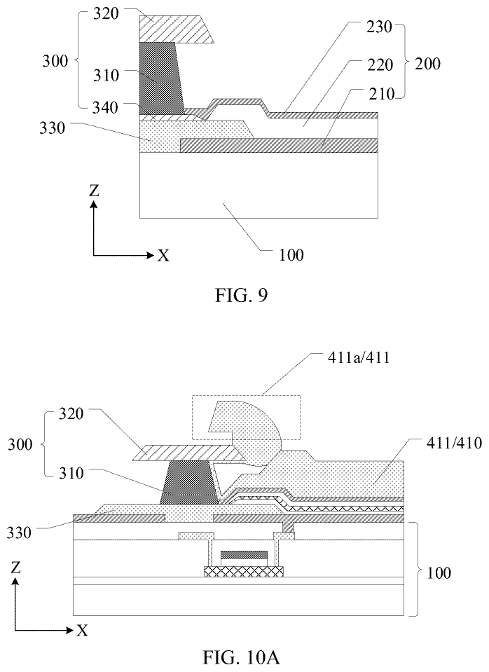

For example, as shown in FIG. 9, on a basis that the support portion 310 is a conductive structure, the isolation structure 300 may further include a conductive layer 340, the conductive layer 340 is located between the support portion 310 and the pixel defining layer 330, and an orthogonal projection, located on the substrate 100, of the end of the support portion 310 close to the substrate 100 is located within an orthogonal projection, located on the substrate 100, of the conductive layer 340, so that the conductive layer 340 is used to support the support portion 310, but a surface of the conductive layer 340 away from the substrate 100 is not completely covered by the support portion 310. Compared with the side surface of the support portion 310, the material used to prepare the second electrode 230 is more easily deposited on a surface of the conductive layer 340 away from the substrate 100, such that the second electrode 230 has a higher thickness on the conductive layer 340, so as to reduce the impedance at a connection between the second electrode 230 and the isolation structure 300.

For example, as shown in FIG. 9, on a basis that the support portion 310 is a conductive structure, an orthogonal projection, located on the substrate 100, of the conductive layer 340 is located within an orthogonal projection, located on the substrate 100, of the crown portion 320, thereby ensuring the isolation effect of the isolation structure 300 on the light-emitting functional layer 220.

For example, as shown in FIG. 9, on a basis that the support portion 310 is a conductive structure, the crown portion 320 can also be further designed as a conductive structure, so that a voltage drop problem generated on the second electrode 230 when the light-emitting unit 200 is driven can be further reduced.

For example, on a basis that the support portion 310 is a conductive structure, the crown portion 320, the support portion 310 and the conductive layer 340 can be prepared from titanium, aluminum and molybdenum in order, and the corrosion resistance of titanium, molybdenum and aluminum decreases sequentially, thereby forming an isolation structure 300 as shown in FIG. 9.

In other embodiments of the present disclosure, a main structure of the isolation structure 300 may tend to be made of an insulating material to ensure a bonding strength with other film layers such as the first packaging layer. For example, as shown in FIG. 9, the support portion 310 and the crown portion 320 are inorganic insulating layers, and the isolation structure 300 further includes a conductive layer 340, which is located between the support portion 310 and the pixel defining layer 330, and an orthogonal projection, located on the substrate 100, of the end of the support portion 310 close to the substrate 100 is located within an orthogonal projection, located on the substrate 100, of the conductive layer 34, and a region of the conductive layer 340 that is not covered by the support portion 310 in a surface away from the substrate 100 is electrically connected to the second electrode 230. As such, the conductive layer 340 can connect the second electrodes 230 of each light-emitting unit 200 together to facilitate connection with an external circuit; the support portion 310 and the crown portion 320 as inorganic insulating layers can have a high bonding strength with the first packaging layer 410 to reduce the risk of interface separation between the first packaging layer 410 and the isolation structure 300.

For example, in a case where the crown portion 320 is an inorganic insulating layer, a thickness of the crown portion 320 may be 500 angstroms to 1500 angstroms.

For example, in a case where the support portion 310 and the crown portion 320 are inorganic insulating layers, a thickness of the conductive layer 340 may be greater than the thickness of the second electrode 230, thereby alleviating a voltage drop problem caused on the second electrode 230 when the light-emitting unit 200 is driven.

For example, in a case where the support portion 310 and the crown portion 320 are inorganic insulating layers, an orthogonal projection, located on the substrate 100, of the conductive layer 340 is located within an orthogonal projection, located on the substrate 100, of the crown portion 320, thereby ensuring the isolation effect of the isolation structure 300 on the light-emitting functional layer 220.

For example, in a case where the crown portion 320 is an inorganic insulating layer, compactness of the crown portion 320 can be set to be greater than compactness of the support portion 310. As such, during the preparation of the isolation structure 300, the support portion 310 can be more easily etched (for example, side-etched) than the crown portion 320, thereby making a size of the crown portion 320 larger than a size of the support portion 310, so as to ensure that the isolation structure 300 has an isolation effect on the light-emitting functional layer 220.

For example, in a case where the crown portion 320 is an inorganic insulating layer, compactness of the crown portion 320 is greater than compactness of the first packaging layer 410. As such, damage to the crown portion 320 in an etching process of preparing the first packaging layer 410 can be reduced to ensure an isolation effect of the isolation structure 300 on the light-emitting functional layer 220.

In at least one embodiment of the present disclosure, referring to FIG. 3 again, the pixel defining layer 330 is an inorganic insulating film layer. As such, the pixel defining layer 330 can separate the conductive structure from the first electrode 210, so that a smaller gap is designed between the first electrode 210, which reduces a pixel gap, thereby improving a pixel density PPI of the display panel; in addition, the inorganic layer has high compactness and strong resistance, such that a design thickness of the display panel can be reduced; in addition, a thickness of the inorganic film layer is relatively small, which makes the pixel opening 302 have a smaller depth to guarantee film layer continuity of the film layer (such as the second electrode 230) formed at the pixel opening 302; in addition, as an inorganic film layer, the pixel defining layer 330 can have a greater bonding strength with the isolation structure 300, thereby reducing risk of the isolation structure 300 falling off.

In at least one embodiment of the present disclosure, referring to FIG. 3 again, the first packaging layer 410 includes a plurality of packaging units 411 that correspond to the isolation openings 301 respectively and cover the light-emitting units 200 in the corresponding isolation openings 301. In a process of preparing the light-emitting units 200 in batches based on the isolation structure 300, the packaging units 411 are formed synchronously with the corresponding light-emitting units 200. After each batch of light-emitting units 200 are prepared, the packaging units 411 can package and protect the prepared light-emitting units 200 in a process of preparing the next batch of light-emitting units 200, so as to ensure a light-emitting effect of the light-emitting units 200.

In the case where the light-emitting units 200 are divided into multiple types that emit light of different colors, the light-emitting units 200 that emit different lights are manufactured independently, but the film layer (evaporated film layer such as a light-emitting functional layer, etc.) in each light-emitting unit 200 is evaporated on an entire surface of the display panel during the evaporation. For example, the light-emitting units 200 are classified into light-emitting units that emit red light (R), green light (G) and blue light (B) respectively. During the preparation process, the light-emitting units R, G and B are sequentially prepared. When preparing the light-emitting unit R, the light-emitting unit R is formed in each isolation opening 301. A first packaging layer 410 is prepared on the display panel to cover the light-emitting unit G. Then, the first packaging layer 410 in some isolation openings 301 (used to form the light-emitting units G and B in the final product) together with the second electrode and the light-emitting functional layer of the light-emitting unit R are removed to obtain the packaging unit 411. During this process, the first packaging layer 410 is used to protect the light-emitting units R in other isolation openings 301. Based on this method, the light-emitting units G and B are sequentially prepared to finally form the first packaging layer 410 as shown in FIG. 3. That is, the first packaging layer 410 on the entire display panel is prepared by multiple processes.

It is to be noted that in the embodiments of the present disclosure, there is no restriction on the preparation order of the three types of light-emitting units R, G, and B, and it can be designed according to the actual process requirements. For example, the preparation process can also be implemented based on the order of light-emitting units B, G, and R.

The reason why the first packaging layer 410 is composed of multiple packaging units 411 is related to the principle that the light-emitting unit 200 is prepared based on the isolation structure 300. For details, please refer to the following relevant descriptions in the embodiments shown in FIGS. 13A to 13I, which will not be redundantly described here.

In at least one embodiment of the present disclosure, referring to FIG. 3 again, at least based on the consideration of improving the packaging effect, the packaging unit 411 can extend to the side of the isolation structure 300 that is away from the substrate 100. The principle thereof can be referred to the following relevant descriptions of the embodiments shown in FIGS. 13A to 13I. In this case, a portion of the packaging unit 411 that overlaps with an upper surface of the isolation structure 300 (the side of the crown portion described below that is away from the substrate) will form an overhang portion 411a to be spaced apart from the crown portion 320. For example, an edge of the packaging unit 411 extends to the side of the pixel defining layer 330 away from the substrate 100, and a portion of the packaging unit 411 located on a side of the pixel defining layer 330 away from the substrate 100 forms the overhang portion 411a with the isolation structure 300.

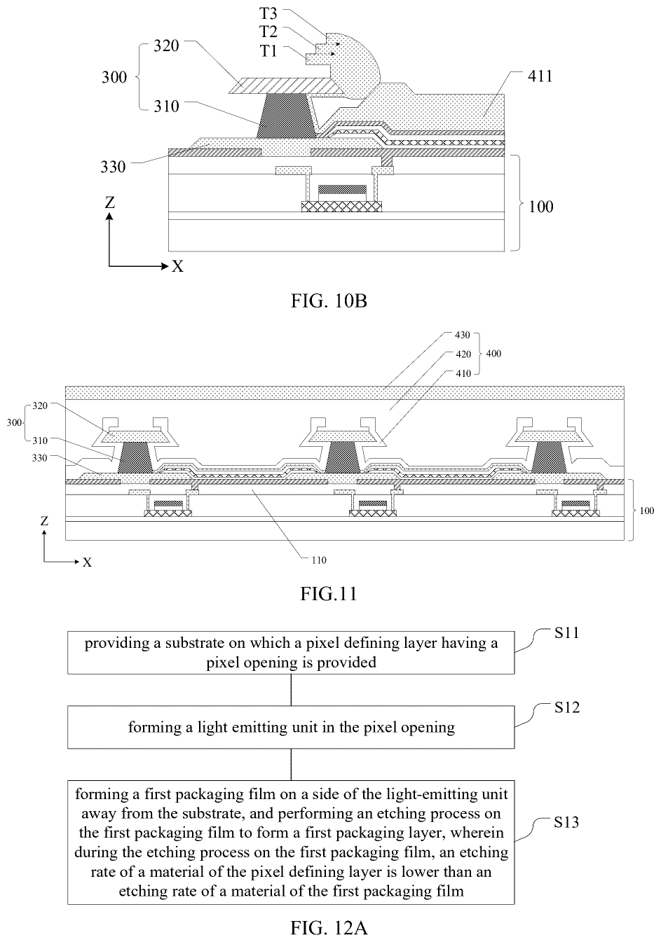

In at least one embodiment of the present disclosure, as shown in FIG. 10A, an orthogonal projection, located on the substrate 100, of a surface of the packaging unit 411 away from the substrate 100 is located within an orthogonal projection, located on the substrate 100, of a surface facing the substrate 100, such that the side surface of the packaging unit 411 is an inclined surface, that is, a plane in which a side surface of the packaging unit 411 is located intersects and is not perpendicular to a plane in which the substrate 100 is located. As such, the side wall of the packaging unit 411 will have a certain slope, such that in the subsequent preparation of the light-emitting unit 200 (not covered by the packaging unit 411 in the subsequent batch), it is convenient to deposit a protective layer (for example, formed in the same layer as the light-emitting functional layer and the second electrode described below) on the side surface to protect the formed packaging unit 411.

For example, along a direction away from the substrate 100, compactness of the first packaging layer 410 gradually decreases, so that a side surface of the packaging unit 411 presents a plane as shown in FIG. 10A.

For example, the packaging unit 411 includes a plurality of sub-packaging layers stacked on one another, and the sub-packaging layer farther from the substrate 100 has smaller compactness. As such, by controlling a compactness distribution of the first packaging layer 410, a relatively inclined surface can be formed at a side surface of the packaging unit 411. As exemplarily shown in FIG. 10B, the packaging unit 411 (or the first packaging layer 410) includes three layers of a first sub-packaging layers T1, a second sub-packaging layer T2 and a third sub-packaging layer T3 stacked on one another. In a process of forming the packaging unit 411, in order to form an inclined side surface, different process conditions are used to make compactness of each of the first sub-packaging layer T1, the second sub-packaging layer T2, and the third sub-packaging layer T3 sequentially decrease. It is to be noted that compactness of the first sub-packaging layer T1, the second sub-packaging layer T2, and the third sub-packaging layer T3 can be constant or gradually changed. In the latter case, a portion closer to the substrate 100 in each sub-packaging layer has greater compactness. It is to be noted that, for the above-mentioned sub-packaging layers, the greater the compactness, the greater the compact degree. As such, by controlling compactness of different sub-packaging layers, a compact degree of different sub-packaging layers can be adjusted, thereby improving flatness of the etched surface of the first packaging layer 410, so that the first packaging layer 410 can be more effectively protected in a preparing process of the display panel.

In some embodiments of the present disclosure, the packaging units 411 corresponding to different light-emitting units 200 are spaced apart from each other, that is, even the packaging units 411 corresponding to adjacent light-emitting units 200 with the same light emission color are spaced apart from each other.

In some embodiments of the present disclosure, the packaging units 411 corresponding to the light emitting units 200 with different light emitting colors are spaced apart from each other, and the packaging units 411 corresponding to the adjacent light emitting units 200 with the same light emitting color are connected to each other. In this case, in the gap between the adjacent light emitting units 200 with the same light emitting color, the crown portion 320 is completely covered by the packaging unit 411, and a film layer is filled between the crown portion 320 and the packaging unit 411. The filled film layer may be of the same layer and the same material as the light-emitting functional layer 220 and the second electrode 230 in an adjacent light emitting unit 200. The principle thereof may be referred to the specific description in the embodiments related to FIGS. 13A to 13I, and will not be redundantly described here.

In at least one embodiment of the present disclosure, as shown in FIG. 11, the display panel may further include a second packaging layer 420 and a third packaging layer 430 covering the first packaging layer 410, the second packaging layer 420 is located between the first packaging layer 410 and the third packaging layer 430, the third packaging layer 430 is located on the side of the second packaging layer 420 away from the substrate 100, and the first packaging layer 410, the second packaging layer 420 and the third packaging layer 430 constitute a packaging structure 400. For example, the second packaging layer 420 is a planar layer. For example, the second packaging layer 420 is an organic film layer, and the third packaging layer 430 is an inorganic film layer. For example, the second packaging layer 420 and the third packaging layer 430 are continuous film layers. The second packaging layer 420 can improve the flatness of the display panel surface to facilitate the arrangement of other components on the packaging layer; in addition, the second packaging layer 420 can have a certain flexibility to relieve the stress of the first packaging layer 410 and the third packaging layer 430, thereby improving reliability of the display panel and being more favourable for the application of the display panel in the field of flexible displays; in addition, the third packaging layer 430 has high compactness and has a high barrier effect against water, oxygen, etc., and the third packaging layer 430 has higher strength to facilitate the preparation of other components thereon (such as structures related to touch functions, optical film layers, etc.).

At least one embodiment of the present disclosure provides a display panel, which can be referred to again in FIGS. 1 to 4 and FIGS. 5A to 5B. The display panel includes a substrate 100 and a pixel defining layer 330 located on the substrate 100. The pixel defining layer 330 includes a first portion and a second portion of different layers, and compactness (or a refractive index) of the first portion is greater than compactness (or a refractive index) of the second portion. The first portion and the second portion can correspond to different sub-defining layers in FIGS. 5A to 5B, that is, the first portion is one of the first sub-defining layer 331, the second sub-defining layer 332 and the third sub-defining layer 333, and the second portion is another one of the first sub-defining layer 331, the second sub-defining layer 332 and the third sub-defining layer 333. By increasing compactness (or a refractive index) of a portion of the pixel defining layer 330, the ability of the pixel defining layer 330 to resist etching in the subsequent preparing process of the display panel can be improved to protect the structure below the pixel defining layer 330, thereby ensuring yield of the display panel; in addition, this solution facilitates the control of the morphology of the side surface of the pixel defining layer 330 (such as the side wall of the pixel defining layer 330 described below) to improve continuity of a film layer formed on the side surface; in addition, this solution allows different portions of the pixel defining layer 330 to be made of different materials, so as to maintain a bonding strength between different film layers adjacent to each other. The specific structure of the display panel and the further design that can be performed can be found with reference to the relevant description in the aforementioned embodiment, and will not be redundantly described here.

In the embodiments of the present disclosure, compactness or a refractive index of the pixel defining layer and the first packaging layer (or at least a portion thereof) can be characterized by other properties such as element (e.g., negatively valent elements) content, etching rate, density, etc., that is, the molecular or atomic compactness of the film layer will affect the above-mentioned properties.

At least one embodiment of the present disclosure provides a display panel, which can be referred to again in FIGS. 1 to 4, the display panel 10 includes a substrate 100 together with a pixel defining layer 330 and a first packaging layer 410 located on the substrate 100, the first packaging layer 410 is located on a side of the pixel defining layer 330 away from the substrate, and a density of at least a portion of the pixel defining layer 330 is greater than a density of the first packaging layer 410. The structure of the display panel, the technical problems to be solved and the corresponding technical effects, and the further improved design structure, etc., can be found with reference to the relevant descriptions in the aforementioned embodiments, and will not be redundantly described here.

For example, in at least one embodiment of the present disclosure, density is used to measure compactness or a refractive index of a film layer, that is, in a case where a density of at least a portion of the pixel defining layer 330 is greater than a density of the first packaging layer 410, the density of at least a portion of the pixel defining layer 330 is also greater than the density of the first packaging layer 410, that is, for a film layer, the greater the compactness, the greater the density. Compactness refers to a ratio of unit mass of a substance to its unit volume. It is usually used to describe a density of solid materials, such as metals, plastics, and glass. Compactness is a commonly used physical parameter that can be used to compare a density difference between different substances. The unit of compactness is usually kilograms per cubic meter (kg/m3), sometimes expressed in grams per cubic centimeter (g/cm3) or pounds per cubic inch (lb/in3). As such, the calculation formula for compactness is density=mass/volume, that is, compactness=mass/volume.

At least one embodiment of the present disclosure provides a display panel, which can be referred to again as shown in FIGS. 1 to 4. The display panel 10 includes a substrate 100 and a pixel defining layer 330 and a first packaging layer 410 located on the substrate 100. The first packaging layer 410 is located on the side of the pixel defining layer 330 away from the substrate 100, and a negative valence element content in at least a portion of the pixel defining layer 330 is greater than a negative valence element content in the first packaging layer 410. For example, the negative valence elements may include oxygen and nitrogen. The structure of the display panel, the technical problems to be solved and the corresponding technical effects, the further improved design structure, etc., can be found with reference to the relevant descriptions in the aforementioned embodiments, and will not be redundantly described here.

For example, the oxygen and nitrogen content of the pixel defining layer 330 and the first packaging layer 410 can be measured by a device such as an oxygen and nitrogen analyzer. During the measurement process, the sample is weighed and placed in a sample port, and through a series of chemical reactions and physical processes, a percentage of oxygen and nitrogen is finally obtained by measuring a gas absorption light intensity and performing calculation using the Lambert-Beer law.

For example, in at least one embodiment of the present disclosure, corresponding to the above-mentioned magnitude relationship about compactness or refractive indexes in the pixel defining layer and the first packaging layer, in a case where a material composition of at least a portion of the pixel defining layer 330 is the same as that of the first packaging layer 410, a negative-valent element content in at least a portion of the pixel defining layer 330 is greater than a negative-valent element content in the first packaging layer 410. In this embodiment, for a portion of the pixel defining layer 330 whose compactness is greater than compactness of the first packaging layer 410, its negative-valent element content is greater than a negative-valent element content of the first packaging layer 410, that is, for a film layer, the greater the negative-valent element content, the greater the compactness.

For example, in at least one embodiment of the present disclosure, the negative valence element includes oxygen or nitrogen. For example, the pixel defining layer 330 and the first packaging layer 410 include at least one of silicon nitride, silicon oxide and silicon oxynitride. For example, a chemical formula of the material of at least a portion of the pixel defining layer 330 is the same as that of the first packaging layer 410, for example, the material of at least a portion of the pixel defining layer 330 and the first packaging layer 410 can be silicon oxide such as silicon oxide, or the material of at least a portion of the pixel defining layer 330 and the first packaging layer 410 can be silicon nitride such as silicon nitride.

For example, in some embodiments of the present disclosure, referring again to FIG. 3 and FIG. 4, the pixel defining layer 330 is a single-layer structure, and a negative valence element content in any portion of the pixel defining layer is greater than a negative valence element content in any portion of the first packaging layer.

For example, in some other embodiments of the present disclosure, referring again to FIGS. 3, 5A and 5B, along a Z-axis direction perpendicular to a plane in which the substrate 100 is located (equivalent to a thickness direction of the pixel defining layer 330), a negative valence element content in the portion of the pixel defining layer 330 away from the substrate 100 (the side close to the first packaging layer 410, such as the second sub-defining layer 332 or the third sub-defining layer 333) is greater than a negative valence element content in the first packaging layer 410, and a negative valence element content in the portion of the pixel defining layer 330 away from the substrate 100 (the side close to the first packaging layer 410) is greater than a negative valence element content in the other portions of the pixel defining layer 330 (the side away from the first packaging layer 410, such as the first sub-defining layer 331 or the second sub-defining layer 332).

For example, as shown in FIG. 5A, along the thickness direction of the pixel defining layer 330, the pixel defining layer 330 includes at least two first sub-defining layers 331 and a second sub-defining layer 332 sequentially stacked on the substrate 100, and a negative valence element content in the second sub-defining layer 332 closest to the first packaging layer 410 is greater than a negative valence element content in the first sub-defining layer 331.

For example, in some examples, as shown in FIG. 5A, a negative-valent element content of the first sub-defining layer 331 closest to the substrate 100 is greater than or equal to a negative-valent element content of the first packaging layer 410.

For example, in other examples, as shown in FIG. 5B, the pixel defining layer 330 includes three first sub-defining layers 331, the second sub-defining layer 332, and the third sub-defining layer 333 which are sequentially stacked on the substrate 100, and the first sub-defining layer 331, the second sub-defining layer 332, and the third sub-defining layer 333 are successively away from the substrate 100, and a negative valence element content in the first sub-defining layer 331, the second sub-defining layer 332, and the third sub-defining layer 333 increases successively.

For example, in some other embodiments of the present disclosure, as shown in FIGS. 3 and 5B, the pixel defining layer 330 includes three first sub-defining layers 331, the second sub-defining layer 332, and the third sub-defining layer 333 which are sequentially stacked on the substrate 100, and the first sub-defining layer 331, the second sub-defining layer 332, and the third sub-defining layer 333 are successively away from the substrate 100, and a negative valence element content in the second sub-defining layer 332 (the middle portion of the pixel defining layer 330) is greater than a negative valence element content in the first packaging layer 410, and a negative valence element content in the second sub-defining layer 332 is greater than a negative valence element content in the first sub-defining layer 331 and the third sub-defining layer 333.

For example, in some examples, as shown in FIGS. 3 and 5B, when a negative valence element content in the middle portion of the pixel defining layer 330, such as the second sub-defining layer 332, is greater than a negative valence element content in the first packaging layer 410, a negative valence element content in the third sub-defining layer 333 farthest from the substrate 100 can be less than or equal to a negative valence element content in the first packaging layer 410.

For example, in some examples, as shown in FIGS. 3 and 5B, when a negative valence element content in the middle portion of the pixel defining layer 330, such as the second sub-defining layer 332, is greater than a negative valence element content in the first packaging layer 410, a negative valence element content in the third sub-defining layer 333 farthest from the substrate 100 is equal to a negative valence element content in the first sub-defining layer 331 closest to the substrate 100, or a negative valence element content in the first sub-defining layer 331 closest to the substrate 100 is less than or equal to a negative valence element content in the first packaging layer 410.

For example, in some other embodiments of the present disclosure, as shown in FIGS. 3 and 5A, along a Z-axis direction perpendicular to a plane in which the substrate 100 is located (which is equivalent to a thickness direction of the pixel defining layer 330), the pixel defining layer 330 includes a first sub-defining layer 331 and a second sub-defining layer 332 sequentially stacked on the substrate 100, and a negative valence element content of the first sub-defining layer 331 is greater than a negative valence element content in the first packaging layer 410, and greater than a negative valence element content in the second sub-defining layer 332.

For example, in some examples, as shown in FIGS. 3 and 5B, the pixel defining layer 330 includes three first sub-defining layers 331, second sub-defining layers 332 and third sub-defining layers 333 sequentially stacked on the substrate 100, and the first sub-defining layers 331, the second sub-defining layers 332 and the third sub-defining layers 333 are successively away from the substrate 100, and a negative valence element content in the first sub-defining layer 331 farthest from the first packaging layer 410 is greater than a negative valence element content in the second sub-defining layers 332 and the third sub-defining layers 333.

For example, in some examples, as shown in FIGS. 3 and 5A, a negative valence element content in the second sub-defining layer 332 is greater than or equal to a negative valence element content in the first packaging layer 410; or, as shown in FIGS. 3 and 5B, a negative valence element content in the third sub-defining layer 333 is greater than or equal to a negative valence element content in the first packaging layer 410.

For example, in some examples, as shown in FIGS. 3 and 5B, the pixel defining layer 330 includes at least three first sub-defining layers 331, the second sub-defining layer 332, and the third sub-defining layer 333 sequentially stacked on the substrate 100, and a negative valence element content in each of the first sub-defining layer 331, the second sub-defining layer 332, and the third sub-defining layer 333 gradually decreases along the direction away from the substrate 100.

At least one embodiment of the present disclosure provides a display panel, which can be referred to again as shown in FIGS. 1 to 4 and FIG. 5A, the display panel 10 includes a substrate 100, and a pixel defining layer 330, a light emitting unit 200, and a packaging structure 400 located on the substrate 100. The pixel defining layer 330 is provided on one side of the substrate 100, the pixel defining layer 330 surrounds and forms a pixel opening 302, the light emitting unit 200 is provided in the pixel opening 302 and on the side of the pixel defining layer 330 away from the substrate 100, the packaging structure 400 is provided on the side of the light-emitting functional layer away from the substrate 100, the packaging structure 400 includes a first packaging layer 410 close to the side of the pixel defining layer 330, the pixel defining layer 330 includes a sub-defining layer, an orthogonal projection, located on the substrate 100, of the first packaging layer 410 partially overlaps with an orthogonal projection, located on the substrate 100, of the sub-defining layer, and an etching rate of the sub-defining layer is lower than an etching rate of the first packaging layer 410.

In the embodiment of the present disclosure, an etching rate may be an etching rate of the etching material used in the etching process of the first packaging layer 410 on the pixel defining layer 330 and the first packaging layer 410.

For example, an etching rate can be measured by the method shown in steps 1 to 4 as follows:
Step 1, selecting the sample material to be etched, cut and dry the sample to be etched, then weigh it, record the mass before etching, and place the weighed sample to be etched on a sample table.
Step 2, selecting an etching process according to the material type of the sample to be etched, and etch the sample material to be etched under certain etching process conditions (ensuring a stable etching environment, such as stable temperature and etching solution concentration).
Step 3, after etching is completed, the etched sample is cleaned and dried and then weighed again, and the weight after etching is recorded.
Step 4, calculating an etching rate using a weight loss method, and the calculation formula is as follows: Δmv=Apt. In the above formula, vis an etching rate; Δm is an etching mass, i.e., a mass difference before and after etching of a sample to be etched; A is an etching area; p is a density of the sample to be etched; tis an etching time. It is to be noted that an etching rate can be measured by other factors, such as the thickness, volume, length, width, etc. of the sample to be etched.

For example, as shown in FIG. 5A, the pixel defining layer 330 includes at least two sub-defining layers, namely, a first sub-defining layer 311 and a second sub-defining layer 312, and the first sub-defining layer 311 is located between the second sub-defining layer 312 and the substrate 100. Under the same etching condition, an etching rate of the second sub-defining layer 312 is lower than an etching rate of the first packaging layer 410.

For example, in some embodiments, as shown in FIG. 5A, an etching rate of the first sub-defining layer 311 is different from that of the second sub-defining layer 312. For example, an etching rate of the first sub-defining layer 311 is greater than an etching rate of the second sub-defining layer 312. As such, in the preparation process of the first packaging layer 410, the second sub-defining layer 312 can be configured to have a higher etching resistance to reduce a degree to which the pixel defining layer 330 is etched and damaged.

For example, as shown in FIG. 5A, a material composition of the first packaging layer 410 is different from that of the second sub-defining layer 312. The material of the first packaging layer 410 includes a silicon-based material containing nitrogen, and the material of the second sub-defining layer 312 includes a silicon-based material containing oxygen. For example, the material of the second sub-defining layer 312 is silicon oxide (such as silicon oxide), and the material of the first packaging layer 410 is silicon nitride (silicon nitride).

For example, as shown in FIG. 5A, a material composition of the first sub-defining layer 311 is different from that of the second sub-defining layer 312. For example, the material of the second sub-defining layer 312 includes a silicon-based material containing oxygen. For example, a material of the second sub-defining layer 312 is silicon oxide (silicon oxide), and a material of the first sub-defining layer 311 is silicon nitride (silicon nitride).

For example, as shown in FIG. 5A, under the same etching condition, an etching rate of the first packaging layer 410 is the same as that of the first sub-defining layer 311, and a material composition of the first sub-defining layer 311 is the same as that of the first packaging layer 410. For example, both of materials of the first sub-defining layer 311 and the first packaging layer 410 are silicon-based materials containing nitrogen, such as silicon nitride.

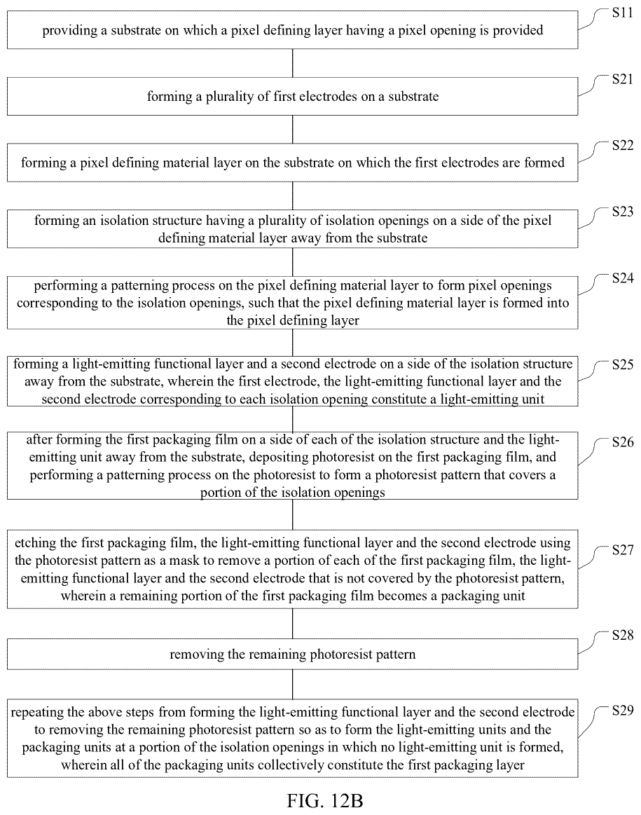

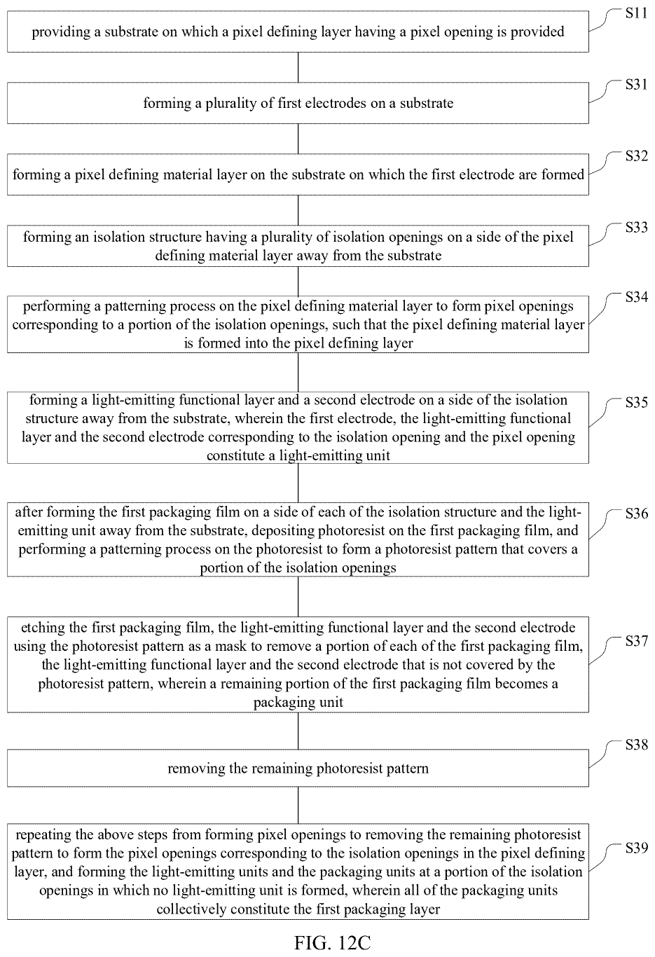

At least one embodiment of the present disclosure provides a method for preparing a display panel. As shown in FIG. 12A, the method includes the following steps S11 to S13.
S11, providing a substrate on which a pixel defining layer having pixel openings is provided.
S12, forming light emitting units in the pixel openings.
S13, forming a first packaging film on a side of the light-emitting units away from the substrate, and performing an etching process on the first packaging film to form a first packaging layer, wherein during the etching process on the first packaging film, an etching rate of a material of the pixel defining layer is lower than an etching rate of a material of the first packaging film.

Regarding the structure of the display panel obtained in the above steps S11 to S13, the technical problems solved and the corresponding technical effects, further improvements, etc., please refer to the relevant descriptions in the above embodiments, and no further details will be given here.

In the preparing method provided in the above embodiment of the present disclosure, as shown in FIG. 12B, the steps of forming the pixel defining layer, the light emitting unit and the first packaging layer in the above steps S12 to S13 include the following steps S21 to S29.
S21, forming a plurality of first electrodes on a substrate.
S22, forming a pixel defining material layer on the substrate on which the first electrodes are formed.
S23, forming an isolation structure having a plurality of isolation openings on a side of the pixel defining material layer away from the substrate.
S24, performing a patterning process on the pixel defining material layer to form pixel openings corresponding to the isolation openings, such that the pixel defining material layer is formed into the pixel defining layer.
S25, forming a light-emitting functional layer and a second electrode on a side of the isolation structure away from the substrate, and the first electrode, the light-emitting functional layer and the second electrode corresponding to each isolation opening constitute a light-emitting unit.
S26, after forming the first packaging film on a side of each of the isolation structure and the light-emitting unit away from the substrate, depositing photoresist on the first packaging film, and performing a patterning process on the photoresist to form a photoresist pattern that covers a portion of the isolation openings.
S27, etching the first packaging film, the light-emitting functional layer and the second electrode using the photoresist pattern as a mask to remove a portion of each of the first packaging film, the light-emitting functional layer and the second electrode that is not covered by the photoresist pattern, wherein the remaining portion of the first packaging film becomes a packaging unit.
S28, removing the remaining photoresist pattern.
S29, repeating the above steps from forming the light-emitting functional layer and the second electrode to removing the remaining photoresist pattern so as to form the light-emitting units and the packaging units at a portion of the isolation openings in which no light-emitting unit is formed, wherein all of the packaging units collectively constitute the first packaging layer.

Regarding the structure of the display panel obtained in the above steps S21 to S29, the technical problems solved and the corresponding technical effects, further improvements, etc., please refer to the relevant descriptions in the above embodiments, and no further details will be redundantly described here.

In another specific embodiment of the fourth aspect of the present disclosure, as shown in FIG. 12C, the steps of forming a pixel defining layer, a light-emitting unit and a first packaging layer in the above steps S12 to S14 include the following steps S31 to S39.
S31, forming a plurality of first electrodes on a substrate.
S32, forming a pixel defining material layer on the substrate on which the first electrodes are formed.
S33, forming an isolation structure having a plurality of isolation openings on a side of the pixel defining material layer away from the substrate.
S34, performing a patterning process on the pixel defining material layer to form pixel openings corresponding to the partial isolation openings, such that the pixel defining material layer is formed into the pixel defining layer.
S35, forming a light-emitting functional layer and a second electrode on a side of the isolation structure away from the substrate, and the first electrode, the light-emitting functional layer and the second electrode corresponding to the isolation opening and the pixel opening constitute a light-emitting unit.
S36, after forming the first packaging film on a side of each of the isolation structure and the light-emitting unit away from the substrate, depositing photoresist on the first packaging film, and performing a patterning process on the photoresist to form a photoresist pattern that covers a portion of the isolation openings.
S37, etching the first packaging film, the light-emitting functional layer and the second electrode using the photoresist pattern as a mask to remove a portion of each of the first packaging film, the light-emitting functional layer and the second electrode that is not covered by the photoresist pattern, wherein the remaining portion of the first packaging film becomes a packaging unit.
S38, removing the remaining photoresist pattern.
S39, repeating the above steps from forming pixel openings to removing the remaining photoresist pattern to form the pixel openings corresponding to the isolation openings in the pixel defining layer, and forming the light-emitting units and the packaging units at a portion of the isolation openings in which no light-emitting unit is formed, wherein all of the packaging units collectively constitute the first packaging layer.

Regarding the structure of the display panel obtained in the above steps S31 to S39, the technical problems solved and the corresponding technical effects, further improvements, etc., please refer to the relevant descriptions in the above embodiments and will not be redundantly described here.

At least one embodiment of the present disclosure provides another method for preparing a display panel, the method including: providing a substrate and forming a pixel defining layer on the substrate; forming a first packaging layer on the substrate formed with the pixel defining layer, wherein, when the preparation conditions of the pixel defining layer and the first packaging layer are the same, the deposition rate of the material of the pixel defining layer is less than the deposition rate of the material of the first packaging layer. In the preparation method, compactness of the prepared pixel defining layer is greater than compactness of the first packaging layer. Regarding the structure of the display panel obtained by the preparation method, the technical problems solved and the corresponding technical effects, further improvements, etc., please refer to the relevant descriptions in the aforementioned embodiments, which will not be redundantly described here.

In the embodiments of the present disclosure, a deposition rate of the pixel defining layer is low (a film forming rate is low), and compactness of the pixel defining layer is high. The deposition rate can be understood as the film forming rate. Under the same process condition or power condition, the smaller the deposition rate (the lower the film forming rate), the more material is deposited at the same position, and the denser the film layer formed.

In the embodiments of the present disclosure, the process conditions may include process types, environmental parameters, etc. For example, the process types may include chemical vapor deposition, atomic layer deposition, or other types of film forming methods, and the environmental parameters may include indoor air pressure, humidity, temperature, etc. For example, power may be a power of inputting materials into a film forming apparatus. The higher the power, the faster the material input and the faster the film forming rate.

For example, the step of forming the pixel defining layer may include: forming a pixel defining material layer on the substrate, and performing an etching process on the pixel defining material layer to form a pixel defining layer having a pixel opening.

For example, the step of forming a first packaging layer may include: forming a first packaging film on a side of the light-emitting unit away from the substrate, and performing an etching process on the first packaging film to form a first packaging layer, wherein the first packaging layer is used to participate in forming a packaging structure, wherein, during the etching process on the first packaging film, the pixel defining layer or the pixel defining material layer is etched at a rate that is lower than an etching rate of the first packaging film.

In at least one embodiment of the present disclosure, the above-mentioned preparation method may further include: forming a first packaging layer on a substrate on which a pixel defining layer is formed. In the preparation method, an input power of the material used to form the first packaging layer is regulated to be greater than an input power of the material used to form the pixel defining layer, so that a film forming rate of the pixel defining layer is less than a film forming rate of the first packaging layer, and thus compactness of the pixel defining layer may be greater than compactness of the first packaging layer. Regarding the structure of the display panel obtained by the preparation method, the technical problems solved and the corresponding technical effects, further improvements, etc., please refer to the relevant descriptions in the aforementioned embodiments, which will not be redundantly described here.

In the embodiments of the present disclosure, a device input power can be controlled during the deposition process (e.g., CVD process) for forming the first packaging layer to control a generation rate of the first packaging layer. When the input power is small, compactness of the first packaging layer will be high; accordingly, when the input power is large, compactness of the first packaging layer will be low. As such, a compactness change of each portion of the first packaging layer can be controlled by controlling the input power.

Next, the preparation process of the display panel shown in FIG. 3 is described in connection with FIGS. 13A to 13I to intuitively demonstrate the principle that the isolation structure can increase a pixel arrangement density PPI.

As shown in FIG. 13A, a substrate 100 is provided, and first electrodes 210 arranged in an array are formed on the substrate 100.

As shown in FIG. 13B, a pixel defining material layer 330a is deposited on the substrate 100 formed with the first electrode 210. In this process, a compactness change of the pixel defining material layer 330a during the formation process can be regulated by controlling a device input power when the pixel defining material layer 330a is deposited.

As shown in FIG. 13C, a first material layer 310 a and a second material layer 320 a are formed on the pixel defining material layer 330a. For example, the material of the first material layer 310 a may be aluminum, and the material of the second material layer 320 a may be titanium.

As shown in FIG. 13D, the first material layer 310a and the second material layer 320a are patterned so that the first material layer 310a is formed into a support portion 310, and the second material layer 320a is formed into a crown portion 320. The support portion 310 and the crown portion 320 define the isolation opening 301 and constitute the isolation structure 300. The specific structure of the isolation structure 300 can be found with reference to the relevant description in the above-mentioned embodiment, which will not be redundantly described here.

In an embodiment of the present disclosure, the patterning process may be a photolithography patterning process, which may include, for example, coating a photoresist on a structure layer to be patterned, exposing the photoresist using a mask, developing the exposed photoresist to obtain a photoresist pattern, etching the structure layer using the photoresist pattern (optionally wet etching or dry etching), and then optionally removing the photoresist pattern. It is to be noted that, in the case where the material of the structure layer (such as the photoresist pattern 500 described below) includes photoresist, the structure layer may be directly exposed through a mask to form a desired pattern.

It is to be noted that if the corrosion resistance of the second material layer 320a (for example, titanium) is greater than that of the first material layer 310a (for example, aluminum), an etching rate of the first material layer 310a will be greater than an etching rate of the second material layer 320a, so that the width of the crown portion 320 will be greater than the width of the support portion 310, so as to form a structure as shown in FIG. 13D.

As shown in FIG. 13E, the pixel defining material layer 330 a is patterned to form a pixel opening 302 at a location where the partial isolation opening 301 is located, and the pixel defining material layer 330 a is formed into a pixel defining layer 330 (not in a final form).

It is to be noted that, in the step shown in FIG. 13E, a photolithography patterning process may be used to form the pixel opening 302. In this process, the isolation structure 300 may also be used to expose the photoresist, thereby precisely controlling the formation position of the pixel opening 302.

As shown in FIG. 13F, the light-emitting functional layer 220 and the second electrode 230 are evaporated on the substrate 100 to form a light-emitting unit 200 in each isolation opening 301 of the isolation structure 300. The evaporation in this process does not use a mask plate, so the evaporated material will also be deposited on the crown portion 320. It is to be noted that in the actual process, the evaporated material will be deposited on the upper surface of the crown portion 320 away from the substrate 100 and the side wall (not shown in the figure); then, the first packaging film 410a is deposited to cover the light-emitting unit 200 and the isolation structure 300. In this process, the input power of the device when the first packaging film 410a is deposited can be controlled to adjust a compactness change of the first packaging film 410a during a formation process.

It is to be noted that the light-emitting functional layer 220 and the first electrode 210 are spaced apart from each other at a position where an isolation opening 301 is formed but a pixel opening 302 is not formed, therefore the light-emitting functional layer 220 and the first electrode 210 of the light-emitting unit 200 at this position are separated from each other and thus have no light-emitting function.

As shown in FIG. 13G, a photoresist is formed (e.g., coated) on the substrate 100 on which the first packaging film 410a is formed, and then patterned to form a photoresist pattern 500 which only covers a portion of the isolation opening 301 of the isolation structure 300 (the isolation opening 301 corresponding to the pixel opening 302).

As shown in FIG. 13H, the surface of the display panel is etched using the photoresist pattern 500 as a mask to remove the first packaging film 410a, the second electrode 230 and the light-emitting functional layer 220 that are not covered by the photoresist pattern 500. The remaining portion of the first packaging film 410a forms the packaging unit 411 of the first packaging layer 410. Then, the remaining photoresist pattern 500 is removed.

It is to be noted that due to the existence of the isolation structure 300 (especially the crown portion 320), the thickness of the first packaging film 410a is relatively thin at a position close to the isolation structure 300. Thus, in the process of etching the surface of the display panel using the photoresist pattern 500 as a mask, the etching material (etching gas or etching liquid) will easily preferentially etch through a thinner portion of the first packaging film 410a, and further etch the pixel defining layer 330 under the first packaging film 410a, thereby damaging the pixel defining layer 330.

As shown in FIG. 13I, the pixel defining layer 330 is patterned to form a pixel opening 302 at a location where another portion of the isolation opening 301 is located (where the pixel opening 302 is not formed).

The steps of FIGS. 13E to 13H are repeated to form a light emitting unit 200 emitting green light and a light emitting unit 200 emitting blue light in other isolation openings 301 respectively, and form the display panel as shown in FIG. 3.

As shown in FIG. 14, when the light-emitting functional layer (such as the first functional layer) is evaporated, if the evaporation source P moves to face the isolation structure 300, a boundary of the evaporation angle corresponds to the line L1 and the line L2 on the display panel, that is, the region before the line L1 and the line L2 will not be evaporated in this case, and the region on the side of the line L1 and the line L2 away from the isolation structure 300 will be evaporated regardless of where the evaporation source P moves. That is, starting from the line L1 or the line L2 area, the closer to the isolation structure 300, the smaller the thickness of the light-emitting functional layer. Similarly, the second electrode can also be formed by evaporation, therefore the closer to the isolation structure 300, the smaller the thickness of the second electrode.

At least one embodiment of the present disclosure provides a display device, which may include the display panel in the above embodiment. For example, the display device may include a touch structure, an optical film (such as a microlens, a polarizer), a cover plate, etc., which are arranged on the light-emitting side of the display panel.

For example, the display device may be any product or component having a display function, such as a television, a digital camera, a mobile phone, a watch, a tablet computer, a notebook computer, a navigator, or the like.

The above description is only a preferred embodiment of this specification and is not intended to limit this specification. Any modifications, equivalent substitutions, etc. made within the spirit and principles of this specification should be included in the protection scope of this specification.

What is claimed is:

1. A display panel, comprising a substrate, a pixel defining layer and a first packaging layer located on the substrate, wherein the first packaging layer is located on a side of the pixel defining layer away from the substrate, and
compactness of at least a portion of the pixel defining layer is greater than compactness of the first packaging layer, or a refractive index of at least a portion of the pixel defining layer is greater than a refractive index of the first packaging layer.

2. The display panel according to claim 1, wherein
along a thickness direction of the pixel defining layer, compactness of a side, close to the first packaging layer, of the pixel defining layer is greater than compactness of the first packaging layer, and compactness of a side, close to the first packaging layer, of the pixel defining layer is greater than compactness of a side, away from the first packaging layer, of the pixel defining layer; or
along a thickness direction of the pixel defining layer, a refractive index of a side, close to the first packaging layer, of the pixel defining layer is greater than a refractive index of the first packaging layer, and a refractive index of a side, close to the first packaging layer, of the pixel defining layer is greater than the refractive index of a side, away from the first packaging layer, of the pixel defining layer.

3. The display panel according to claim 2, wherein the pixel defining layer comprises at least two sub-defining layers sequentially stacked on the substrate, and
compactness of one sub-defining layer, close to the first packaging layer, of the at least two sub-defining layers is greater than compactness of the sub-defining layer away from the first packaging layer, or a refractive index of one sub-defining layer, close to the first packaging layer, of the at least two sub-defining layers is greater than a refractive index of the sub-defining layer away from the first packaging layer.

4. The display panel according to claim 1, wherein
along a thickness direction of the pixel defining layer, compactness of a middle portion of the pixel defining layer is greater than compactness of the first packaging layer, and compactness of a middle portion of the pixel defining layer is greater than compactness of other portions of the pixel defining layer; or
along a thickness direction of the pixel defining layer, a refractive index of a middle portion of the pixel defining layer is greater than a refractive index of the first packaging layer, and a refractive index of a middle portion of the pixel defining layer is greater than a refractive index of other portions of the pixel defining layer.

5. The display panel according to claim 1, wherein
along a thickness direction of the pixel defining layer, compactness of the pixel defining layer close to the substrate is greater than compactness of the first packaging layer, and compactness of a portion of the pixel defining layer close to the substrate is greater than compactness of other portions of the pixel defining layer; or
along a thickness direction of the pixel defining layer, a refractive index of the pixel defining layer close to the substrate is greater than a refractive index of the first packaging layer, and the refractive index of a portion of the pixel defining layer close to the substrate is greater than the refractive index of other portions of the pixel defining layer.

6. The display panel according to claim 1, wherein the pixel defining layer is a single-layer structure, and
compactness of the pixel defining layer is greater than compactness of the first packaging layer, or a refractive index of the pixel defining layer is greater than a refractive index of the first packaging layer.

7. The display panel of claim 1, wherein each of the pixel defining layer and the first packaging layer includes at least one of silicon nitride, silicon oxide and silicon oxynitride.

8. A display panel, comprising a substrate and a pixel defining layer located on the substrate, wherein a surface of the pixel defining layer away from the substrate is a first surface, and a surface of the pixel defining layer close to the substrate is a second surface, an orthogonal projection, located on the substrate, of the first surface is located within an orthogonal projection, located on the substrate, of the second surface, the pixel defining layer comprises a side wall, the side wall connects the first surface and the second surface, and is provided obliquely relative to a plane in which the substrate is located, and
the pixel defining layer includes at least two sub-defining layers stacked on the substrate.

9. The display panel according to claim 8, wherein the side wall is a continuous surface, and
along a direction perpendicular to a plane in which the substrate is located, the sectional shape of the side wall of the pixel defining layer is a straight line segment; or
along a direction perpendicular to a plane in which the substrate is located, a sectional shape of the side wall of the pixel defining layer is a line segment formed by sequentially connecting a plurality of straight line segments end to end, and angles at which lines in which the plurality of straight line segments are located intersect with the plane in which the substrate is located are different; or
along a direction perpendicular to a plane in which the substrate is located, a sectional shape of the side wall of the pixel defining layer is a line segment formed by connecting a plurality of curved segments connected end to end, and the plurality of curved segments have different curvatures; or
along a direction perpendicular to a plane in which the substrate is located, a sectional shape of the side wall of the pixel defining layer is a line segment comprising a first curved line segment, a straight line segment and a second curved line segment connected to each other.

10. The display panel according to claim 8, wherein the sidewall of the pixel defining layer is a stepped surface, the at least two sub-defining layers include a first sub-defining layer and a second sub-defining layer,
along a direction away from the substrate, the first sub-defining layer and the second sub-defining layer are sequentially stacked on one side of the substrate, and an orthogonal projection, located on the substrate, of the second sub-defining layer is located within an orthogonal projection, located on the substrate, of the first sub-defining layer, and
along a direction perpendicular to a plane in which the substrate is located, the sectional shape of the sidewalls of the first sub-defining layer and the second sub-defining layer is a first line segment, and a plurality of first line segments are arranged in a disconnected manner.

11. The display panel according to claim 8, wherein the at least two sub-defining layers include a first sub-defining layer and a second sub-defining layer, and along a direction away from the substrate, the first sub-defining layer and the second sub-defining layer are sequentially stacked on one side of the substrate;
compactness of the second sub-defining layer is greater than compactness of the first sub-defining layer, or a refractive index of the second sub-defining layer is greater than a refractive index of the first sub-defining layer, or under the same etching condition, an etching rate of the second sub-defining layer is lower than an etching rate of the first sub-defining layer; or
a material of the first sub-defining layer and the second sub-defining layer includes at least one of silicon nitride, silicon oxide and silicon oxynitride.

12. The display panel according to claim 8, wherein in a section perpendicular to a plane in which the substrate is located, an angle between a straight line in which a side wall of the pixel defining layer is located and the plane in which the substrate is located is not greater than 45 degrees.

13. The display panel according to claim 8, wherein the at least two sub-defining layers include a first sub-defining layer and a second sub-defining layer,
along a direction away from the substrate, the first sub-defining layer and the second sub-defining layer are sequentially stacked on one side of the substrate, and
a thickness of the first sub-defining layer is greater than a thickness of the second sub-defining layer,
the pixel defining layer has a thickness of 2000 angstroms to 5000 angstroms, the first sub-defining layer has a thickness of 2000 angstroms to 3000 angstroms, and the second sub-defining layer has a thickness of 500 angstroms to 1000 angstroms.

14. The display panel according to claim 8, further comprising a plurality of light-emitting units,
wherein the pixel defining layer comprises a plurality of pixel openings, the light-emitting units are confined in the pixel openings, the light-emitting unit comprise a first electrode, a light-emitting functional layer and a second electrode that are sequentially stacked on the substrate, the first electrode is located between the pixel defining layer and the substrate, the pixel openings expose a portion of the first electrode, and
the light-emitting functional layer and the second electrode cover the pixel openings and extend to a side, away from the substrate, of the pixel defining layer.

15. The display panel according to claim 14, further comprising an isolation structure located on the pixel defining layer, the isolation structure defining a plurality of isolation openings corresponding to the pixel openings, the light-emitting functional layer and the second electrode being located in the isolation openings, the second electrode being electrically connected to the isolation structure, and the isolation structure includes a support portion and a crown portion, wherein the support portion is located between the crown portion and the substrate, and an orthogonal projection, located on the substrate, of the support portion is located within an orthogonal projection, located on the substrate, of the crown portion.

16. The display panel according to claim 15, wherein the isolation structure comprises a conductive layer between the support portion and the pixel defining layer, and an orthogonal projection, located on the substrate, of an end of the support portion close to the substrate is located within an orthogonal projection, located on the substrate, of the conductive layer.

17. The display panel according to claim 8, further comprising a first packaging layer provided on a side, away from the substrate, of the pixel defining layer, and
compactness of at least a portion of the pixel defining layer is greater than compactness of the first packaging layer, or
a refractive index of at least a portion of the pixel defining layer is greater than a refractive index of the first packaging layer, or
under the same etching condition, an etching rate of at least a portion of the pixel defining layer is lower than an etching rate of the first packaging layer.

18. A display panel, comprising:
a substrate;
a pixel defining layer that is provided on one side of the substrate, wherein the pixel defining layer surrounds a plurality of pixel openings;
a light emitting unit that is provided in the pixel opening and on a side of the pixel defining layer away from the substrate;
a packaging structure that is provided on a side, away from the substrate, of the light-emitting functional layer, the packaging structure includes a first packaging layer close to the pixel defining layer, the pixel defining layer includes a sub-defining layer, an orthogonal projection, located on the substrate, of the first packaging layer partially overlaps with an orthogonal projection, located on the substrate, of the sub-defining layer, and an etching rate of the sub-defining layer is lower than an etching rate of the first packaging layer.

19. The display panel according to claim 18, wherein the sub-defining layer comprises a first sub-defining layer and a second sub-defining layer, the first sub-defining layer is located between the second sub-defining layer and the substrate, and under the same etching condition, an etching rate of the second sub-defining layer is lower than an etching rate of the first packaging layer;
an etching rate of the first sub-defining layer is greater than an etching rate of the second sub-defining layer.

20. The display panel according to claim 19, wherein a material composition of the first packaging layer is different from that of the second sub-defining layer, the material of the first packaging layer comprises a silicon-based material containing nitrogen, and the material of the second sub-defining layer comprises a silicon-based material containing oxygen;
the material of the second sub-defining layer is silicon oxide, and the material of the first packaging layer is silicon nitride.
